(19) United States
(12) Patent Application Publication
(10) Pub. No.: US 2025/0391459 A1
(43) Pub. Date: Dec. 25, 2025

(54) MEMORY DEVICES AND METHODS FOR PERFORMING POWER EFFICIENCY MODE OPERATIONS

(71) Applicant: SAMSUNG ELECTRONICS CO., LTD., Suwon-si (KR)

(72) Inventors: Seungki Hong, Suwon-si (KR); Jihwan Seol, Suwon-si (KR); Kiheung Kim, Suwon-si (KR); Hoseok Seol, Suwon-si (KR); Wonho Choi, Suwon-si (KR); Jinyong Choi, Suwon-si (KR)

(21) Appl. No.: 19/020,969

(22) Filed: Jan. 14, 2025

(30) Foreign Application Priority Data
Jun. 19, 2024 (KR) 10-2024-0079801

(51) Int. Cl. G11C 11/4074; G11C 11/4076; G11C 11/408

(52) U.S. Cl. CPC G11C 11/4074; G11C 11/4076; G11C 11/4087

(57) ABSTRACT

Provided are a memory device and a method for performing power efficiency mode operations. The memory device includes a first command address (CA) circuit and a second CA circuit, wherein the first CA circuit generates a first sub-channel command signal, a second sub-channel command signal, and a first sub-channel address signal based on first command address signals of first sub-channel signals, and the second CA circuit generates a third sub-channel command signal, a fourth sub-channel command signal, and a second sub-channel address signal based on second command address signals of second sub-channel signals. In the power efficiency mode, the first CA circuit is disabled and the second CA circuit generates the first sub-channel address signal in response to the third sub-channel command signal.

### CROSS-REFERENCE TO RELATED APPLICATION

This application is based on and claims priority under 35 U.S.C. § 119 to Korean Patent Application No. 10-2024-0079801, filed on Jun. 19, 2024, in the Korean Intellectual Property Office, the disclosures of which are incorporated by reference herein in their entirety.

### BACKGROUND

The power consumption of electronic devices is crucial feature. Power consumption of a memory system is a critical element of the power budget of an electronic device and occupies a significant portion of the overall system power consumption. A memory system includes a memory having a large number of dynamic random access memories (DRAMs) implemented on a plurality of individual DRAM chips. Low Power Double Data Rate Synchronous DRAM (LPDDR SDRAM) may be used in mobile systems such as smartphones, tablet personal computers (PCs), and ultra books. As the capacity of a mobile operating system (OS) increases to support multi-tasking operations performed on a mobile system, a memory device with higher speed operation performance and lower power consumption characteristics is demanded. Low-power operation of a memory device may conserve power of a mobile system and extend the battery life thereof.

### SUMMARY

The present disclosure provides memory devices and methods for performing power efficiency mode operations for reducing power consumption of memory devices.

According to an aspect of the present disclosure, a memory device is provided for supporting a power efficiency mode, the memory device including a memory cell array region including a plurality of memory cells, wherein the memory cell array region includes a first sub-channel memory cell array region and a second sub-channel memory cell array region, a plurality of signal pins connected to a plurality of signal lines, wherein the plurality of signal pins include first sub-channel signal pins and second sub-channel signal pins, the first sub-channel signal pins are configured to receive first sub-channel signals associated with the first sub-channel memory cell array region, and the second sub-channel signal pins are configured to receive second sub-channel signals associated with the second sub-channel memory cell array region, a first command address circuit configured to receive first command address signals of the first sub-channel signals and generate a first sub-channel command signal, a second sub-channel command signal, and a first sub-channel address signal based on the first command address signals, and a second command address circuit configured to receive second command address signals of the second sub-channel signals and generate a third sub-channel command signal, a fourth sub-channel command signal, and a second sub-channel address signal based on the second command address signals, wherein, in the power efficiency mode, the first command address circuit is configured to be disabled and the second command address circuit is configured to generate the first sub-channel address signal in response to the third sub-channel command signal.

According to another aspect of the present disclosure, a memory device is provided for supporting a power efficiency mode, the memory device including a memory cell array region including a plurality of memory cells, wherein the memory cell array region includes a first sub-channel memory cell array region and a second sub-channel memory cell array region, a plurality of signal pins connected to a plurality of signal lines, wherein the plurality of signal pins include first sub-channel signal pins and second sub-channel signal pins, the first sub-channel signal pins are configured to receive first sub-channel signals associated with the first sub-channel memory cell array region, and the second sub-channel signal pins are configured to receive first sub-channel signals associated with the second sub-channel memory cell array region, a first command address circuit configured to receive first command address signals of the first sub-channel signals and generate a first sub-channel command signal, a second sub-channel command signal, and a first sub-channel address signal based on the first command address signals, a second command address circuit configured to receive second command address signals of the second sub-channel signals and generate a third sub-channel command signal, a fourth sub-channel command signal, and a second sub-channel address signal based on the second command address signals, and an even-cycle detection circuit configured to even-number clock signal cycles based on the clock signal when a first chip select signal is input after power-down of the memory device and detect whether a command is applied in an even-numbered clock cycle.

According to another aspect of the present disclosure, a memory device is provided for supporting a power efficiency mode, the memory device including a clock circuit configured to receive a clock signal, a memory cell array region including a plurality of memory cells, wherein the memory cell array region includes a first sub-channel memory cell array region and a second sub-channel memory cell array region, a plurality of signal pins connected to a plurality of signal lines, wherein the plurality of signal pins include first sub-channel signal pins and second sub-channel signal pins, the first sub-channel signal pins are configured to receive first sub-channel signals associated with the first sub-channel memory cell array region, and the second sub-channel signal pins are configured to receive first sub-channel signals associated with the second sub-channel memory cell array region, a first command address circuit configured to receive first command address signals of the first sub-channel signals and generate a first sub-channel command signal, a second sub-channel command signal, and a first sub-channel address signal based on the first command address signals, and a second command address circuit configured to receive second command address signals of the second sub-channel signals and generate a third sub-channel command signal, a fourth sub-channel command signal, and a second sub-channel address signal based on the second command address signals, wherein the first command address circuit and the second command address circuit are disabled such that the first and second sub-channel command signals and the third and fourth sub-channel command signals are not generated based on a logic level of a chip select signal of the first command address signals and the second command address signals at a first rising edge and a second rising edge of the clock signal.

### BRIEF DESCRIPTION OF THE DRAWINGS

Implementations of the present disclosure will be more clearly understood from the following detailed description taken in conjunction with the accompanying diagrams in which:

FIG. 1 is a block diagram of an example of apparatus;

FIGS. 2A, 2B, and 2C are diagrams illustrating example memory devices performing power efficiency mode operations;

FIGS. 3A, 3B, and 3C are diagrams illustrating example memory devices performing power efficiency mode operations;

FIGS. 4A and 4B are diagrams illustrating power consumption characteristics in a normal mode and a power efficiency mode performed by the apparatus of FIG. 1;

FIG. 5 is a diagram illustrating a command applied to an example of a memory device;

FIG. 6 is a diagram illustrating example command address circuits of a memory device;

FIG. 7 is a circuit diagram illustrating a command decoder circuit of FIG. 6;

FIGS. 8 to 10 are timing diagrams illustrating the operation of the command address circuit of FIG. 6;

FIGS. 11, 12, and 13 are diagrams illustrating the operation of the command address circuit of FIG. 6;

FIGS. 14A and 14B are diagrams illustrating example command address circuits of a memory device;

FIG. 15 is a diagram illustrating example command address circuits of a memory device; and

FIG. 16 is a block diagram of an example system to describe an electronic device including a semiconductor integrated circuit.

### DETAILED DESCRIPTION

A memory device described herein may be divided into logical and/or physical groups in terms of power control and address designation/memory access by a memory controller, and may be implemented with, for example, low power double data rate (LPDDR) synchronous dynamic random access memory (SDRAM). When a read command and a related address are provided to a memory device by a memory controller, the memory device may receive the read command and the related address, perform a read operation, and output a read data DQ from a memory location corresponding to the related address. When a write command and a related address are provided to a memory device by a memory controller, the memory device may receive the write command and the related address and perform a write operation to write a write data DQ from the memory controller to a memory location corresponding to the related address.

The LPDDR SDRAM may include a memory circuit, process access to data and commands stored in the memory circuit, and perform other control and/or configuration operations. The LPDDR SDRAM may store information used to configure the operation of the LPDDR SDRAM in a mode register set (hereinafter referred to as an “MRS”) to set operating conditions. The MRS may store a parameter code indicating whether it is in a normal mode or a power efficiency mode (sometimes referred to as a dynamic efficiency mode).

Each LPDDR SDRAM may communicate with a memory controller through an individual channel. Individual channels are implemented as buses including signal lines through which commands/addresses, data, and clock signals are transmitted and may each be operated independently. Various clock signals may be provided between the memory controller and a memory device via a clock bus. The clock bus may include signal lines for providing system clocks CK_t and CK_c received by the memory device, data clocks WCK_t and WCK_c received by the memory device, and a read clock provided by the memory device to the memory controller. The clock signals CK_t and CK_c provided to the memory devices by the memory controller are used for timings of providing and receiving commands and addresses. Clock signals WCK_t and WCK_c are used for timings for providing data. The clock signals CK_t and CK_c are complementary to each other, and the clock signals WCK_t and WCK_c are complementary to each other. For example, when the rising edge of a clock signal CK_t occurs simultaneously with the falling edge of a clock signal CK_c and when the rising edge of the clock signal CK_c occurs simultaneously with the falling edge of the clock signal CK_t, the clock signals CK_t and CK_c are complementary to each other. The clock signals WCK_t and WCK_c are synchronized with the clock signals CK_t and CK_c and may have higher clock frequencies than those of the clock signals CK_t and CK_c. The clock signals CK_t and CK_c may be referred to as clock signals CK, and the clock signals WCK_t and WCK_c may be referred to as clock signals WCK.

Depending on the development stage of LPDDR SDRAM, a memory architecture in which existing channels are each divided into a plurality of sub-channels and each sub-channel operates independently is designed. Therefore, each LPDDR SDRAM may be connected to at least two sub-channels, and each sub-channel within the LPDDR SDRAM may be designed to operate independently. Hereinafter, to reduce power consumption of LPDDR SDRAM(s), LPDDR SDRAM that performs power efficiency mode operations related to sub-channels by utilizing a command address circuit (sometimes referred to as a CA circuit) is provided.

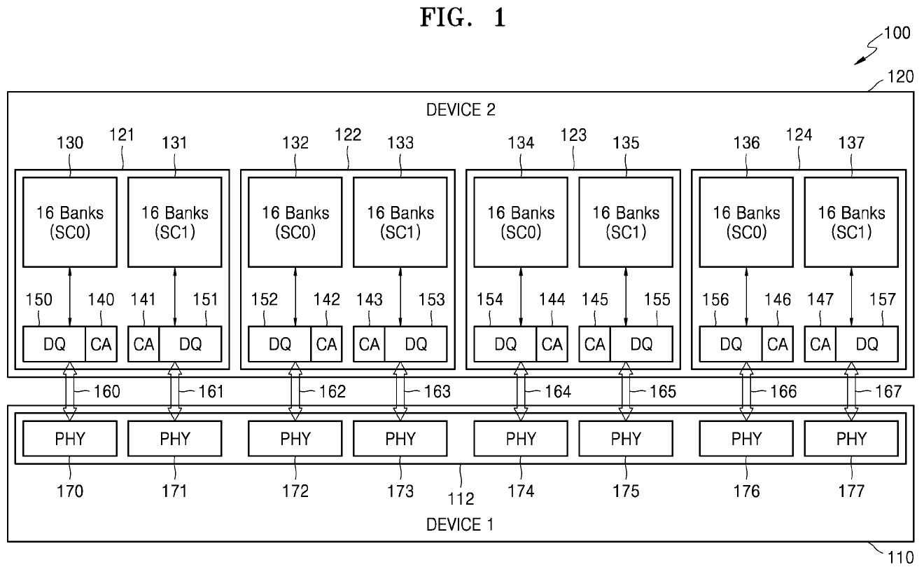

FIG. 1 is a block diagram of an example apparatus. Referring to FIG. 1, an apparatus 100 includes a first device 110 and a second device 120. The apparatus 100 may be implemented to be included in a personal computer (PC) or a mobile electronic device. The mobile electronic device may be implemented as a laptop computer, a mobile phone, a smartphone, a tablet PC, a personal digital assistant (PDA), an enterprise digital assistant (EDA), a digital still camera, a digital video camera, a portable multimedia player (PMP), a personal navigation device or a portable navigation device (PND), a handheld game console, a mobile internet device (MID), a wearable computer, an internet of things (IoT) device, an internet of everything (IoE) device, or a drone.

For example, the first apparatus 110 may be implemented by a system-on-chip (SoC), an application processor (AP), a mobile AP, a chipset, an integrated circuit (IC), or a set of chips. For example, the first device 110 may be a semiconductor device that performs a memory control function, and the first device 110 may be a component included in an AP. An AP may include a memory controller, random access memory (RAM), a central processing unit (CPU), a graphics processing unit (GPU), and/or a modem.

The second device 120 may be implemented by a volatile memory device. The volatile memory device may include RAM, dynamic RAM (DRAM), or static RAM (SRAM) but is not limited thereto. For example, the second device 120 may correspond to double data rate synchronous dynamic random access memory (DDR SDRAM), low power double data rate LPDD (LPDDR) SDRAM, graphics double data rate (GDDR) SDRAM, Rambus dynamic random access memory (RDRAM), etc. Alternatively, the second device 120 may be implemented by high bandwidth memory (HBM).

In some implementations, the second device 120 is implemented by a non-volatile memory device. For example, the second device 120 may be implemented by a resistive memory such as phase change RAM (PRAM), magnetic RAM (MRAM), or resistive RAM (RRAM). Hereinafter, for convenience of explanation, the first device 110 is referred to as a memory controller, and the second device 120 is referred to as a memory system. The memory system 120 may include n (n is a non-zero whole number) memory devices 121 to 124.

The memory devices 121 to 124 may each include bank groups (e.g., 130 and 131) including a plurality of banks (e.g., 16 banks), and each bank may include a plurality of memory cell rows (or pages). Bank groups 130, 131, 132, 133, 134, 135, 136, and 137 of the memory devices 121 to 124 may refer to memory cell array regions respectively accessed through sub-channels 160 to 167 that operate independently of each other. The configuration including 16 banks and 2 bank groups shown in FIG. 1 as an example does not represent or imply limitations on the present disclosure. For example, the memory cell array may include 4 bank groups with 4 banks per bank group, 8 banks, or 16 banks, depending on the configuration of 16, 12, or 8 data signals implemented in sub-channels 160 to 167.

The bank groups 130, 131, 132, 133, 134, 135, 136, and 137 of the memory devices 121 to 124 may include command address circuits (CA circuits 140 to 147) and data circuits (DQ circuits 150 to 157) respectively connected to corresponding sub-channels 160 to 167. The CA circuits 140 to 147 may each receive a command and an address together with the command through a corresponding sub-channel of the sub-channels 160 to 167 and capture an address at which the corresponding command is to be executed. The DQ circuits 150 to 157 may receive write data transmitted from the memory controller 110 through respectively corresponding sub-channels 160 to 167 and transmit read data respectively output from the bank groups 130, 131, 132, 133, 134, 135, 136, and 137 to the memory controller 110.

The memory controller 110 may include a memory PHY group 112 including memory PHYs 170 to 177 that provide precise operation timings to perform memory operations for the memory devices 121 to 124. The memory PHYs 170 to 177 may each include a physical or electrical layer and a logical layer provided for signals, frequencies, timings, driving strengths, detailed operation parameters, and functionality needed for efficient communication between the memory controller 110 and the memory devices 121 to 124. The memory PHYs 170 to 177 may support the features of a low power double data rate (LPDDR) protocol of the Joint Electron Device Engineering Council (JEDEC) standard.

The memory PHYs 170 to 177 may access corresponding bank groups 130, 131, 132, 133, 134, 135, 136, and 137 through the CA circuits 140 to 147 and the DQ circuits 150 to 157 connected to corresponding sub-channels 160 to 167, respectively. This means that each of the bank groups 130, 131, 132, 133, 134, 135, 136, and 137 is accessed by a corresponding sub-channel of the sub-channels 160 to 167. For example, a first sub-channel 160 may be configured to access a first bank group 130, and a second sub-channel 161 may be configured to access a second bank group 131. In implementations below, for convenience of explanation, the bank groups 130, 131, 132, 133, 134, 135, 136, and 137 may each be referred to as a memory region of a corresponding sub-channel.

In some implementations, a first memory PHY 170 enables a first CA circuit 140 and a first DQ circuit 150 via the first sub-channel 160 and accesses a first sub-channel memory region 130. A second memory PHY 171 may enable a second CA circuit 141 and a second DQ circuit 151 via the second sub-channel 161 and access a second sub-channel memory region 131. A third memory PHY 172 may enable a third CA circuit 142 and a third DQ circuit 152 via a third sub-channel 162 and access a third sub-channel memory region 132. A fourth memory PHY 173 may enable a fourth CA circuit 143 and a fourth DQ circuit 153 via a fourth sub-channel 163 and access a fourth sub-channel memory region 133. A fifth memory PHY 174 may enable a fifth CA circuit 144 and a fifth DQ circuit 154 via a fifth sub-channel 164 and access a fifth sub-channel memory region 134. A sixth memory PHY 175 may enable a sixth CA circuit 145 and a sixth DQ circuit 155 via a sixth sub-channel 165 and access a sixth sub-channel memory region 135. A seventh memory PHY 176 may enable a seventh CA circuit 146 and a seventh DQ circuit 156 via a seventh sub-channel 166 and access a seventh sub-channel memory region 136. An eighth memory PHY 177 may enable an eighth CA circuit 147 and an eighth DQ circuit 157 via an eighth sub-channel 167 and access an eighth sub-channel memory region 137.

FIG. 1 illustrates an example in which the memory controller 110 activates all of first to eighth sub-channels 160 to 167 and accesses first to eighth sub-channel memory regions 130 to 137, which means that the memory devices 121 to 124 perform normal mode operations under the control by the memory controller 110.

In some implementations, the memory controller 110 activates some of the first to eighth sub-channels 160 to 167 and deactivates the remaining sub-channels. For example, the memory controller 110 may activate sub-channels numbered with even numbers (e.g., 160, 162, 164, and 166) of the first to eighth sub-channels 160 to 167 and deactivate sub-channels numbered with odd numbers (e.g., 161, 163, 165, and 167). For example, the memory controller 110 may activate sub-channels numbered with odd numbers (e.g., 161, 163, 165, and 167) of the first to eighth sub-channels 160 to 167 and deactivate sub-channels numbered with even numbers (e.g., 160, 162, 164, and 166). This means that the memory devices 121 to 124 perform power efficiency mode operations under the control by the memory controller 110.

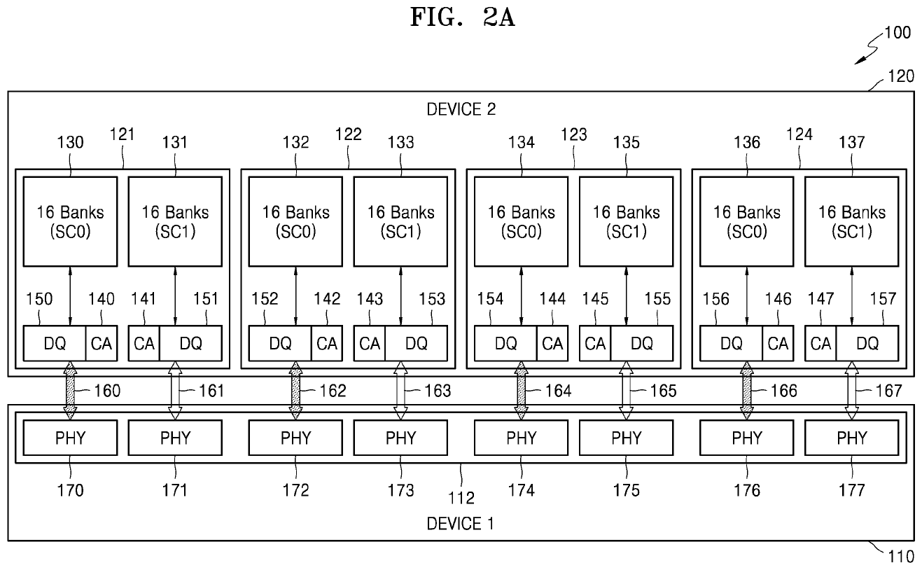

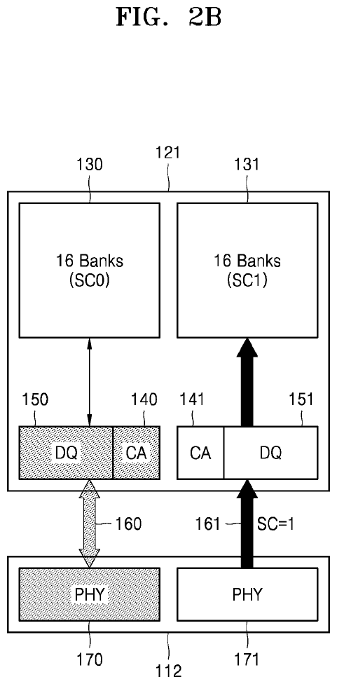

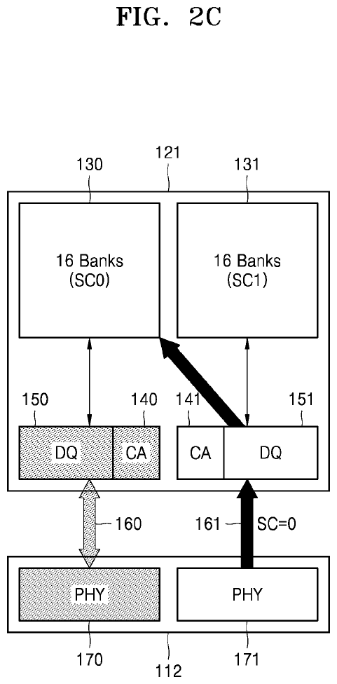

FIGS. 2A, 2B, and 2C are diagrams illustrating the example memory devices 121 to 124 performing power efficiency mode operations. FIG. 2A illustrates an example in which the memory controller 110 deactivates first, third, fifth, and seventh sub-channels 160, 162, 164, and 166 numbered with even numbers and activates second, fourth, sixth, and eighth sub-channels 161, 163, 165, and 167 numbered with odd numbers, based on power efficiency mode parameters set in the MRS of the memory devices 121 to 124 under the control by the memory controller 110. To simplify the circuit relationships, components in a disabled state are shadowed, because they do not operate.

Referring to FIG. 2A, a deactivated even-numbered first sub-channel 160 (hereinafter referred to as an “SC0 channel”) may be connected in a disabled state to a first memory device 121, and an activated odd-numbered second sub-channel 161 (hereinafter referred to as an “SC1 channel”) may be connected to the first memory device 121. Deactivated even-numbered sub-channels 162, 164, and 166 and activated odd-numbered sub-channels 163, 165, and 167 may also be connected to second to fourth memory devices 122, 123, and 124, respectively. The descriptions of the operations of an SC0 channel 160 and an SC1 channel 161 of the first memory device 121 may be equally applied to the second to fourth memory devices 122, 123 and 124. In the below descriptions, a memory device refers to the first memory device 121.

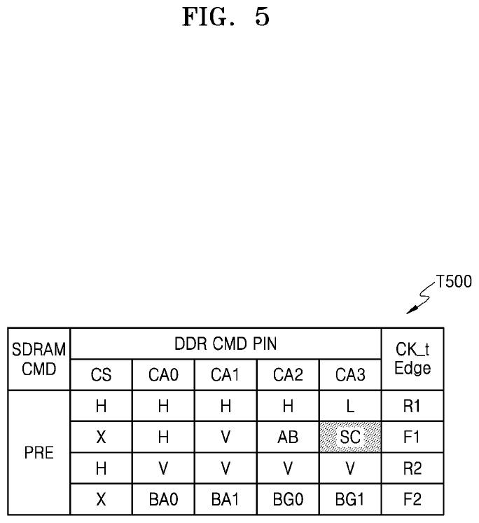

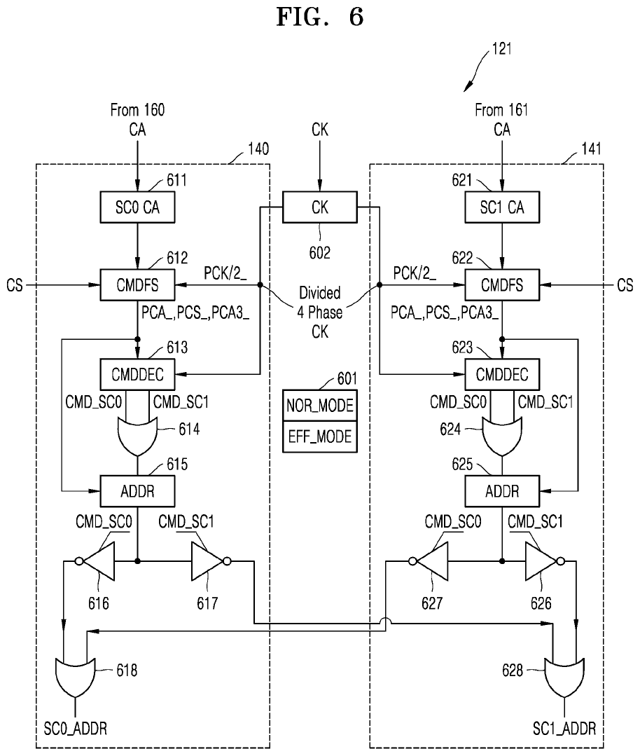

Referring to FIG. 2B, when operating in the power efficiency mode, the memory controller 110 may access an SC1 memory region 131 by using the activated SC1 channel 161. This may be determined by a sub-channel signal SC (FIG. 5) transmitted through a CA signal line of the SC1 channel 161. For example, when the sub-channel signal SC is set to a logic high level (i.e., when SC=1), the memory controller 110 may access the SC1 memory region 131 by using the SC1 channel 161.

Meanwhile, in FIG. 2B, the memory controller 110 may attempt to execute a command accessing the SC1 memory region 131 in an SC0 memory region 130. This may occur when the memory controller 110 executes user-requested commands (e.g., read/write commands) to process jobs or tasks of a host. When the memory controller 110 accesses the SC0 memory region 130, a command timing delay may occur, because a disabled SC0 channel 160 and the first CA circuit 140 connected to the SC0 channel 160 need to be activated due to operations of sub-channels being independent of each other. Therefore, sub-channel efficiency deteriorates. To improve the sub-channel efficiency, as shown in FIG. 2C, the memory controller 110 may be designed to access the SC0 memory region 130 by using the activated SC1 channel 161.

Referring to FIG. 2C, when operating in the power efficiency mode, the memory controller 110 may access an SC0 memory region 130 by using the activated SC1 channel 161. When the sub-channel signal SC transmitted through the CA signal line of the SC1 channel 161 is set to a logic low level (i.e., when SC=0), the memory controller 110 may access the SC0 memory region 130 by using the SC1 channel 161.

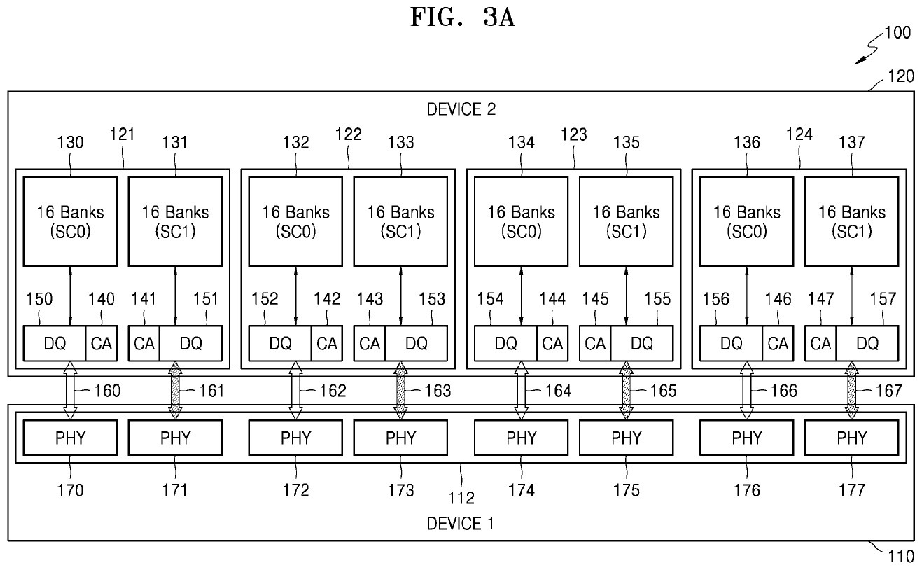

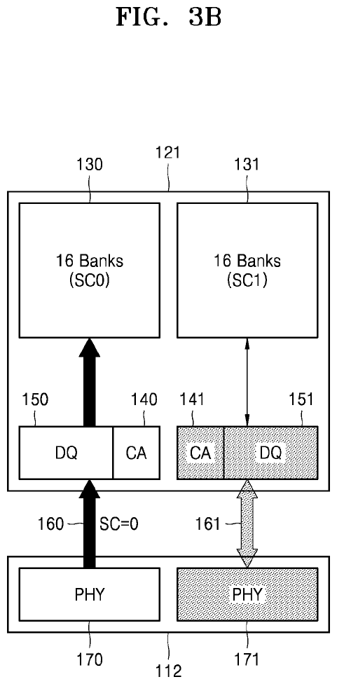

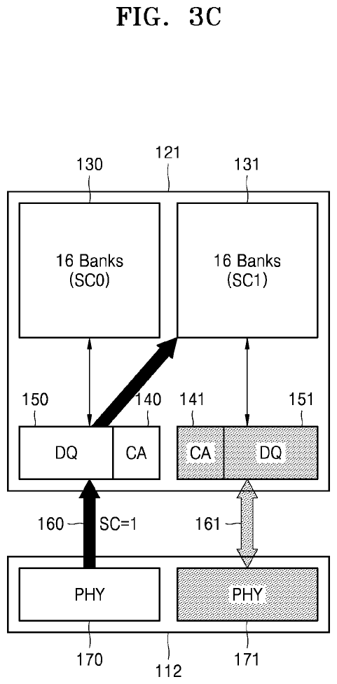

FIGS. 3A, 3B, and 3C are diagrams illustrating the memory devices 121 to 124 performing power efficiency mode operations according to some implementations of the present disclosure. FIG. 3A illustrates an example in which the memory controller 110 deactivates the second, fourth, sixth, and eighth sub-channels 161, 163, 165, and 167 numbered with odd numbers and activates the first, third, fifth, and seventh sub-channels 160, 162, 164, and 166 numbered with even numbers, based on power efficiency mode parameters set in the MRS of the memory devices 121 to 124 under the control by the memory controller 110.

Referring to FIG. 3A, the deactivated odd-numbered second sub-channel 161 may be connected in a disabled state to the memory device 121 and the activated even-numbered first sub-channel 160 may be connected to the memory device 121. Deactivated odd-numbered sub-channels 163, 165, and 167 and activated even-numbered sub-channels 162, 164, and 166 may also be connected to second to fourth memory devices 122, 123, and 124, respectively.

Referring to FIG. 3B, when operating in the power efficiency mode, the memory controller 110 may access the SC0 memory region 130 by using the activated SC0 channel 160. When the sub-channel signal SC transmitted through a CA signal line of the SC0 channel 160 is set to a logic low level (i.e., when SC=0), the memory controller 110 may access the SC0 memory region 130 by using the SC0 channel 160.

Referring to FIG. 3C, when operating in the power efficiency mode, the memory controller 110 may access the SC1 memory region 131 by using the activated SC0 channel 160. When the sub-channel signal SC transmitted through the CA signal line of the SC0 channel 160 is set to a logic high level (i.e., when SC=1), the memory controller 110 may access the SC1 memory region 131 by using the SC0 channel 160.

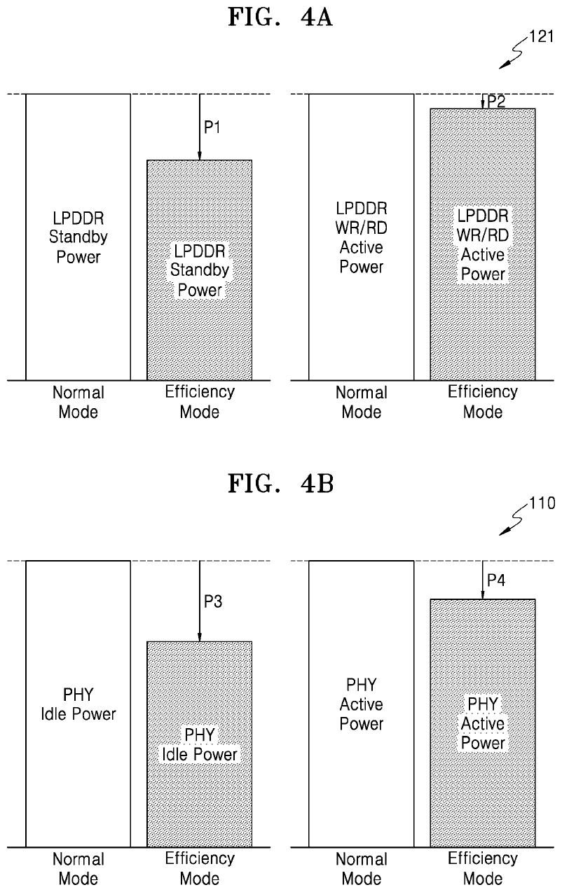

FIGS. 4A and 4B are diagrams illustrating power consumption characteristics in a normal mode and a power efficiency mode performed by the apparatus 100 of FIG. 1. FIG. 4A is a diagram illustrating power consumption in the memory device 121, wherein the memory device 121 consumes an IDD2N or IDD3N parameter current specified in the LPDDR SDRAM in a standby state in which the memory device 121 is not accessed, and consumes an IDD4W/R parameter current in an active state in which the memory device 121 performs write/read operations. FIG. 4B is a diagram illustrating power consumption of the memory controller 110. For convenience of explanation, the term ‘power efficiency mode’ may be used interchangeably with the term ‘efficiency mode’.

Referring to FIG. 4A, it may be seen that, when the memory device 121 is in a standby state, the power consumption of the memory device 121 is reduced by about first power P1 in an environment (FIG. 2A) in which an efficiency mode operation is set between the memory controller 110 and the memory device 121 compared to the power consumption of the memory device 121 in an environment (FIG. 1) in which a normal mode operation is set between the memory controller 110 and the memory device 121. This means that, as compared to the power consumption in the normal mode in which both the SC0 channel 160 and the SC1 channel 161 are enabled, and CA circuits 140 and 141 and DQ circuits 150 and 151 connected to the SC0 channel 160 and the SC1 channel 161 are enabled, the power consumption in the efficiency mode in which any one of the SC0 channel 160 and the SC1 channel 161 (i.e., the SC0 channel 160) is disabled, and the first CA circuit 140 and the first DQ circuit 150 connected to the disabled SC0 channel 160 is lower. It may be seen that, when the memory device 121 is in an active state, the power consumption of the memory device 121 in the efficiency mode of FIG. 2A is also reduced by about second power P2 as compared to the power consumption of the memory device 121 in the normal mode of FIG. 1.

Referring to FIG. 4B, in terms of the power consumption of the memory controller 110 when the memory PHYs 170 to 177 are in an idle state, it may be seen that, as compared to the power consumption in the normal mode of FIG. 1, the power consumption in the efficiency mode of FIG. 2A is reduced by about third power P3. This means that the power consumption in the efficiency mode in which odd-numbered sub-channels (e.g., 161, 163, 165, and 167) are activated and even-numbered sub-channels (e.g., 160, 164, 166, and 168) are deactivated is lower than the power consumption in the normal mode in which all of the sub-channels 160 to 167 are enabled. It may be seen that, in terms of the power consumption when the memory PHYs 170 to 177 of the memory controller 110 are in an active state, the power consumption in the efficiency mode of FIG. 2A is reduced by about fourth power P4 as compared to the power consumption in the normal mode of FIG. 1.

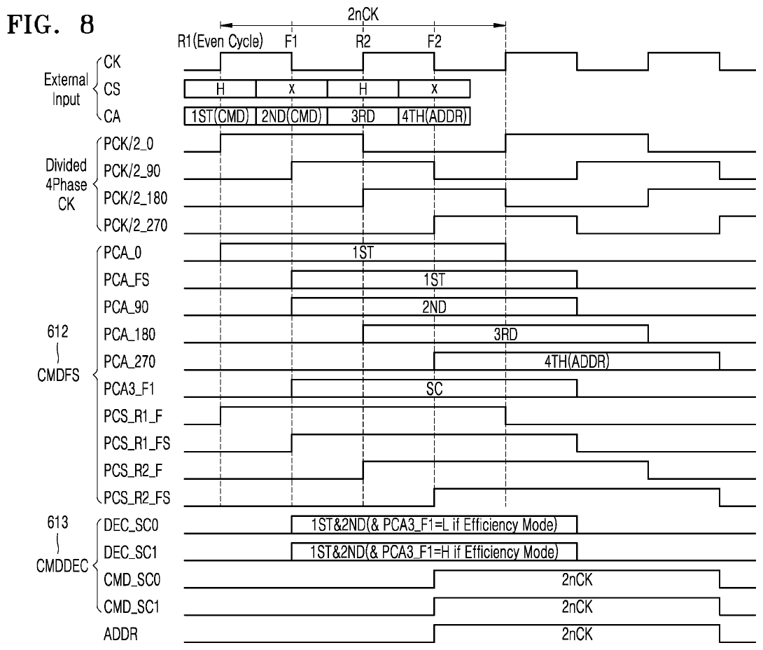

FIG. 5 is a diagram illustrating an example command applied to a memory device. In FIG. 5, the number of clock signals nCK needed to define a command in a memory PHY may be set to, for example, two clock cycles (2nCK, FIG. 8).

Referring to FIG. 5, a pre-charge command diagram T500 is shown. Operands of a pre-charge command PRE are provided from a chip select signal CS and column addresses CA[0] to CA[3]. Operands of the pre-charge command PRE may be provided from the chip select signal CS and the column addresses CA[0] to CA[3] at a first rising edge R1, a first falling edge F1, and a second rising edge R2 of a clock signal CK, and address operands to execute the pre-charge command PRE may be input at a second falling edge F2 of the clock signal CK.

The operands (variables, fields, or values indicating particular aspects of the pre-charge command PRE) may include BG0, BG1, BA0, BA1, AB, and SC provided according to the LPDRAM specification. The V indicates a defined logic level of “H” or “L”, and the X indicates ‘don't care’. BG0 and BG1 may indicate bank group addresses, BA0 and BA1 may indicate bank addresses, and AB may indicates all banks. SC may indicate a sub-channel memory region that is accessed in the power efficiency mode. An SC “0” bit value may indicate accessing an SC0 memory region (e.g., 130), and an SC “1” bit value may indicate accessing an SC1 memory region (e.g., 131).

As shown in FIG. 8, by using the chip select signal CS and the column addresses CA[0] to CA[3], the chip select signal CS at a logic level “H” and a first operand of the pre-charge command PRE may be input at the first rising edge R1 of the clock signal CK, a second operand of the pre-charge command PRE may be input at the first falling edge F1 of the clock signals CK, the chip select signal CS at a logic level “H” and a third operand of the pre-charge command PRE may be input at the second rising edge R2 of the clock signal CK, and a fourth operand (sometimes referred to as an address operand) may be input at the second falling edge F2 of the clock signal CK.

In some implementations, non-limiting examples of commands include a power-down command, an active command, a read command, a write command, a mode register write command, a mode register read command, a CAS command, a refresh command, a training command, etc. with respect to the memory device 121.

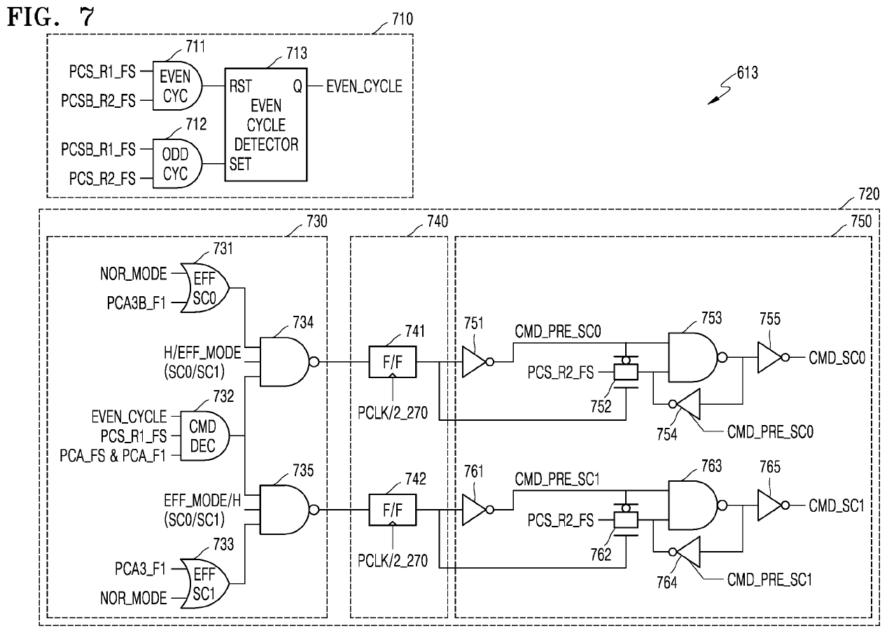

FIG. 6 is a diagram illustrating the example CA circuits 140 and 141 of the memory device 121. In FIG. 6, since the first CA circuit 140 is associated with the SC0 memory region 130, the first CA circuit 140 is referred to as an SC0 CA circuit 140. Since the second CA circuit 141 is associated with the SC1 memory region 131, the second CA circuit 141 is referred to as an SC1 CA circuit 141. FIG. 7 is a circuit diagram illustrating an example command decoder circuit 613 of FIG. 6. FIGS. 8 to 10 are timing diagrams illustrating the operation of the CA circuit 140 of FIG. 6. In the timing diagrams, the horizontal axis and the vertical axis represent time and voltage levels, respectively, and are not necessarily drawn to scale.

Referring to FIG. 6, the memory device 121 may include an MRS 601 in which a parameter code indicating a normal mode or an efficiency mode is stored. The memory device 121 may generate a normal mode signal NOR_MODE based on a normal mode parameter code stored in the MRS 601 and may generate an efficiency mode signal EFF_MODE based on an efficiency mode parameter code stored in the MRS 601.

The memory device 121 may include a clock circuit 602 that receives the clock signal CK transmitted from the memory controller 110. The clock circuit 602 may divide the clock signal CK by two to generate a division clock signal, and generate multi-phase clock signals that are phase-divided from the division clock signal CK. The division clock signal can be also referred to as the divided-by-two clock signal CK in present disclosure. The multi-phase clock signals may include first to fourth phase clock signals PCK/2_0, PCK/2_90, PCK/2_180, and PCK/2_270 (FIG. 8) having a phase relationship of 90 degrees (0 degrees, 90 degrees, 180 degrees, and 270 degrees) with respect to one another. The first to fourth phase clock signals PCK/2_0, PCK/2_90, PCK/2_180, and PCK/2_270 may be provided to the SC0 CA circuit 140 and the SC1 CA circuit 141.

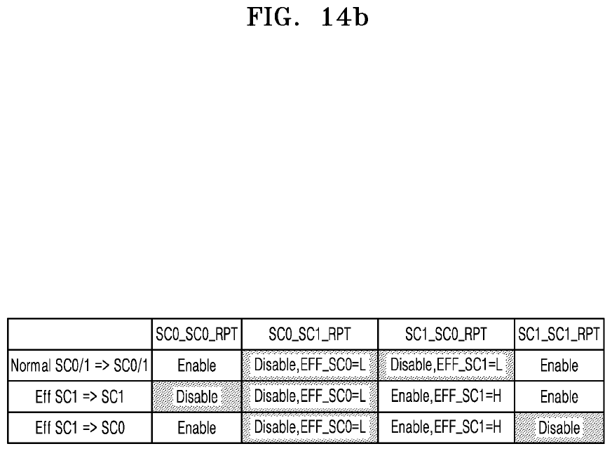

In some implementations, the memory device 121 receives a separate clock signal CK for each sub-channel. As shown in FIG. 14A, the memory device 121a may divide the clock signal CK, which is received by a first clock circuit 1402 for an SC0 channel and by a second clock circuit 1404 for an SC1 channel, by two and generate a multi-phase clock signal that is phase-divided from a divided-by-two clock signal CK.

Referring back to FIG. 6, the SC0 CA circuit 140 may include a CA buffer circuit 611, a command capturing circuit 612, the command decoder circuit 613, a first logic circuit 614, an address capturing circuit 615, a first buffer 616, a second buffer 617, and a second logic circuit 618.

The CA buffer circuit 611 may receive a CA signal transmitted from the memory controller 110 through the SC0 channel 160. A signal that swings to the current mode logic (CML) level may be used as the CA signal. The CML level refers to a scheduled direct current (DC) level or an average level determined according to a certain criterion. A signal swinging at the CML level is a signal that is toggled with an amplitude or a swing range based on the DC level called the CML level. For example, when the level of a power voltage VDD of the memory device 121 is about 1.2 V and the level of a ground voltage VSS of the memory device 121 is 0 V, the CML level of the signal swinging at the CML level may be about 1.0 V, and the swing width thereof may be about 0.5 V. The swing width of a CML level signal is relatively small as compared to the Complementary Metal Oxide Semiconductor (CMOS) level, which is the digital signal level of internal signals of the memory device 121. A CMOS level signal fully swings from the level of the power voltage VDD level to the level of the ground voltage VSS. Since the swing width of a CML level signal is smaller than that of a CMOS level signal, the CML level signal may operate with relatively low power supply and high-speed switching. The CA buffer circuit 611 may convert a CA signal swinging at the CML level into a CA signal swinging at the CMOS level and transmit the CA signal swinging at the CMOS level to the command capturing circuit 612.

The command capturing circuit 612 may capture the chip select signal CS and the CA signal at the CMOS level output from the CA buffer circuit 611 in response to the first to fourth phase clock signals PCK/2_0, PCK/2_90, PCK/2_180, and PCK/2_270. As shown in FIG. 8, the command capturing circuit 612 may capture the CA signal and the chip select signal CS in response to a first phase clock signal PCK/2_0 and output them as a first CA signal PCA_0 and a first CS signal PCS_R1_F, and may capture the first CA signal PCA_0 and the first CS signal PCS_R1_F in response to a second phase clock signal PCK/2_90 and output them as a first command operand signal PCA_FS and a second CS signal PCS_R1_FS.

The command capturing circuit 612 may capture the CA signal in response to the second phase clock signal PCK/2_90 and output a captured CA signal as a second command operand signal PCA_F1, and may capture a column address CA[3] from the CA signal and use a captured column address CA[3] as a sub-channel designation signal PCA3_F1. For example, when the sub-channel signal SC set to the column address CA[3] is set to a logic high level (i.e., when SC=1), the sub-channel designation signal PCA3_F1 may also be configured to be output at a logic high level to access the SC1 memory region 131. When the sub-channel signal SC set to the column address CA[3] is set to a logic low level (i.e., when SC=0), the sub-channel designation signal PCA3_F1 may also be configured to be output at a logic low level to access the SC0 memory region 130.

The command capturing circuit 612 may capture the CA signal and the chip select signal CS in response to a third phase clock signal PCK/2_180 and output them as a third command operand signal PCA_180 and a third CS signal PCS_R2_F. The command capturing circuit 612 may capture the CA signal and the third CS signal PCS_R2_F in response to a fourth phase clock signal PCK/2_270 and output them as a fourth command operand signal PCA_270 and a fourth CS signal PCS_R2_FS. The fourth command operand signal PCA_270 may be referred to as an address operand signal. The command capturing circuit 612 may transfer the first command operand signal PCA_FS, the second command operand signal PCA_F1, the second CS signal PCS_R1_FS, and the sub-channel designation signal PCA3_F1 to the command decoder circuit 613 and provide the fourth command operand signal PCA_270 to the address capturing circuit 615.

In some implementations, the command capturing circuit 612 inverts the second CS signal PCS_R1_FS to output an inverted second CS signal PCSB_R1_FS and inverts the fourth CS signal PCS_R2_FS to output an inverted fourth CS signal PCSB_R2_FS. As illustrated in the pre-charge command diagram T500 of FIG. 5, since the chip select signal CS is set to a logic high level, when the pre-charge command PRE is normally applied to the memory device 121, the second CS signal PCS_R1_FS and the inverted fourth CS signal PCSB_R2_FS is output at a logic high level, and the inverted second CS signal PCSB_R1_FS and the fourth CS signal PCS_R2_FS is output at a logic low level.

Referring back to FIG. 6, the command decoder circuit 613 may generate an SC0 command signal CMD_SC0 for accessing the SC0 memory region 130 and an SC1 command signal CMD_SC1 for accessing the SC1 memory region 131, based on the first command operand signal PCA_FS, the second command operand signal PCA_F1, the second CS signal PCS_R1_FS, and the sub-channel designation signal PCA3_F1.

In some implementations, the memory device 121 processes a demand at even-number cycles of the clock signal CK based on the clock signal CK when the first chip select signal CS is input after power-down. The memory device 121 may determine that a command applied in an even-numbered clock cycle is valid and that a command applied in an odd-numbered clock cycle is invalid. The command decoder circuit 613 may activate an even cycle signal EVEN_CYCLE when a command is applied in an even-numbered clock cycle and decode the first command operand signal PCA_FS, the second command operand signal PCA_F1, and the second CS signal PCS_R1_FS in response to the activated even cycle signal EVEN_CYCLE. The command decoder circuit 613 may include an even-cycle signal generating circuit 710 and a sub-channel command signal generating circuit 720, as shown in FIG. 7.

Referring to FIG. 7, the even-cycle signal generating circuit 710 may include a first logic circuit 711, a second logic circuit 712, and an even cycle detection circuit 713. The first logic circuit 711 may receive the second CS signal PCS_R1_FS and the inverted fourth CS signal PCSB_R2_FS to perform an AND logic operation and provide an output signal of the AND logic operation to a reset terminal RST of the even cycle detection circuit 713. The second logic circuit 712 may receive the inverted second CS signal PCSB_R1_FS and the fourth CS signal PCS_R2_FS to perform an AND logic operation and provide an output signal of the AND logic operation to a set terminal SET of the even cycle detection circuit 713. The even cycle detection circuit 713 may reset the even cycle signal EVEN_CYCLE to a logic low level in response to a logic low level of the reset terminal RST and set the even cycle signal EVEN_CYCLE to a logic high level in response to a logic low level of the set terminal SET.

When a command is normally applied in an even-numbered clock cycle, an output signal of the first logic circuit 711 may be output at a logic high level in response to the second CS signal PCS_R1_FS and the inverted fourth CS signal PCSB_R2_FS at a logic high level, and an output signal of the second logic circuit 712 may be output at a logic low level in response to the inverted second CS signal PCSB_R1_FS and the fourth CS signal PCS_R2_FS applied at a logic low level. The even cycle detection circuit 713 may output the even cycle signal EVEN_CYCLE at a logic high level in response to a logic low level of the set terminal SET. The even cycle signal EVEN_CYCLE at a logic high level may function as an enable signal of the sub-channel command signal generating circuit 720.

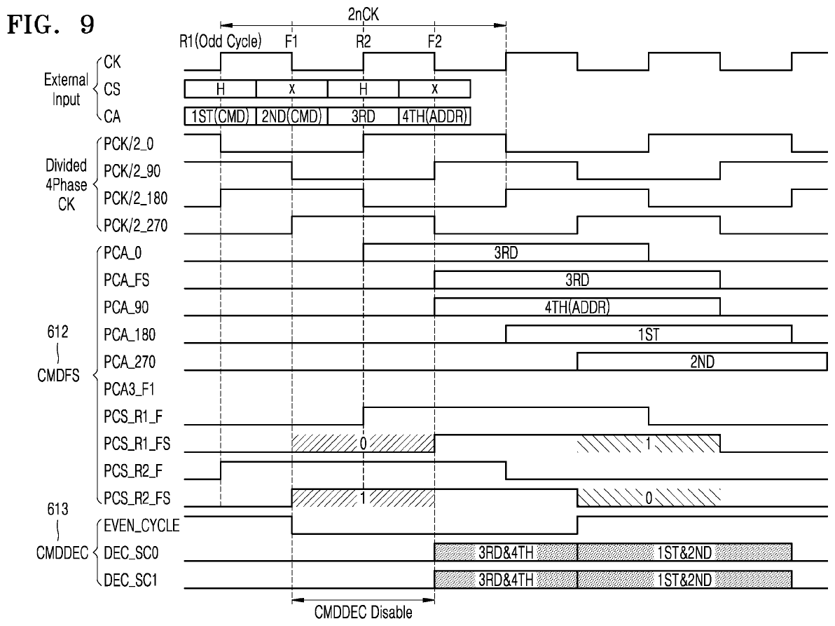

Conversely, as shown in FIG. 9, a command may be applied abnormally in an odd-numbered clock cycle. Referring to FIG. 9, in response to the second CS signal PCS_R1_FS at a logic low level, an output signal of the first logic circuit 711 may be output at a logic low level, and, in response to the inverted second CS signal PCSB_R1_FS and the fourth CS signal PCS_R2_FS applied at a logic high level, an output signal of the second logic circuit 712 may be output at a logic high level. The even cycle detection circuit 713 may output the even cycle signal EVEN_CYCLE at a logic low level in response to an output signal of the first logic circuit 711 at a logic low level provided to the reset terminal RST. The command decoder circuit 613 may be disabled by the even cycle signal EVEN_CYCLE at a logic low level.

In FIG. 7, the sub-channel command signal generating circuit 720 may include a command decode signal generating circuit 730, a command window centering circuit 740, and a sub-channel command signal generating circuit 750.

The command decode signal generating circuit 730 may include first to fifth logic circuits 731 to 735. The first logic circuit 731 may receive the normal mode signal NOR_MODE and an inverted sub-channel designation signal PCA3B_F1 to perform an OR logic operation on the normal mode signal NOR_MODE and an inverted sub-channel designation signal PCA3B_F1 and provide an output signal of the OR logic operation to the fourth logic circuit 734. The second logic circuit 732 may receive the even cycle signal EVEN_CYCLE, the second CS signal PCS_R1_FS, the first command operand signal PCA_FS, and the second command operand signal PCA_F1 to perform an AND logic operation on the even cycle signal EVEN_CYCLE, the second CS signal PCS_R1_FS, the first command operand signal PCA_FS, and the second command operand signal PCA_F1 and provide an output signal of the logic operations to fourth and fifth logic circuits 734 and 735. The third logic circuit 733 may receive the normal mode signal NOR_MODE and the sub-channel designation signal PCA3_F1 to perform an OR logic operation and provide an output signal of the OR logic operation to the fifth logic circuit 735. The fourth logic circuit 734 may receive the output signal of the first logic circuit 731, the efficiency mode signal EFF_MODE, and the output signal of the second logic circuit 732 to perform a NAND logic operation on the output signal of the first logic circuit 731, the efficiency mode signal EFF_MODE, and the output signal of the second logic circuit 732 to output a first sub-channel decode signal DEC_SC0. The fifth logic circuit 735 may receive an output signal of the second logic circuit 732, the efficiency mode signal EFF_MODE, and the output signal of the third logic circuit 733 to perform a NAND logic operation on the output signal of the second logic circuit 732, the efficiency mode signal EFF_MODE, and the output signal of the third logic circuit 733 and output a second sub-channel decode signal DEC_SC1.

In some implementations, when a command is abnormally applied in an odd-numbered clock cycle, the command decode signal generating circuit 730 is disabled as the even cycle signal EVEN_CYCLE at a logic low level is provided thereto. This means that a command applied normally in an even-numbered clock cycle becomes the starting point of the operation of disabling the command decoder circuit 613 in connection with the operation of the even-cycle signal generating circuit 710 described with reference to FIGS. 7 and 9.

In some implementations, when the memory device 121 is in a normal mode, the command decode signal generating circuit 730 outputs the first sub-channel decode signal DEC_SC0 by the fourth logic circuit 734 and outputs the second sub-channel decode signal DEC_SC1 by the fifth logic circuit 735. This means that the SC0 channel 160 described with reference to FIG. 1 is connected to the SC0 CA circuit 140, and the SC1 channel 161 is connected to the SC1 CA circuit 141 in the normal mode.

In some implementations, when the memory device 121 is in an efficiency mode and the sub-channel designation signal PCA3_F1 is captured at a logic high level, the fourth logic circuit 734 of the command decode signal generating circuit 730 is disabled, and the command decode signal generating circuit 730 outputs the second sub-channel decode signal DEC_SC1 by the fifth logic circuit 735. This means that the power efficiency mode operation is associated with an SC=1 efficiency mode of accessing the SC1 memory region 131 in the SC1 CA circuit 141 connected to the SC1 channel 161 described with reference to FIG. 2B, or an SC=1 efficiency mode of accessing the SC1 memory region 131 in the SC0 CA circuit 140 connected to the SC0 channel 160 described with reference to FIG. 3C.

In some implementations, when the memory device 121 is in an efficiency mode and the sub-channel designation signal PCA3_F1 is captured at a logic low level, the command decode signal generating circuit 730 outputs the first sub-channel decode signal DEC_SC0 by the fourth logic circuit 734, and the fifth logic circuit 735 is disabled. This means that the power efficiency mode operation is associated with the SC=0 efficiency mode of accessing the SC0 memory region 130 in the SC1 CA circuit 141 connected to the SC1 channel 161 described with reference to FIG. 2C, or the SC=0 efficiency mode of accessing the SC0 memory region 130 in the SC0 CA circuit 140 connected to the SC0 channel 160 described with reference to FIG. 3B.

The command window centering circuit 740 may include a first flip-flop circuit 741 and a second flip-flop circuit 742. The first flip-flop circuit 741 may latch the first sub-channel decode signal DEC_SC0 in response to the fourth phase clock signal PCK/2_270, and the second flip-flop circuit 742 may latch the second sub-channel decode signal DEC_SC1 in response to the fourth phase clock signal PCK/2_270. Therefore, as shown in FIG. 8, a latched first sub-channel decode signal DEC_SC0 and a latched second sub-channel decode signal DEC_SC1 may be centered around the fourth phase clock signal PCK/2_270.

The sub-channel command signal generating circuit 750 may include a first inverter 751, a first transmission gate 752, a first logic circuit 753, a first tri-state buffer 754, and a second inverter 755. The first inverter 751 may input the first sub-channel decode signal DEC_SC0, output a first sub-channel command preparation signal CMD_PRE_SC0k and provide the first sub-channel command preparation signal CMD_PRE_SC0 to the first logic circuit 753. The first sub-channel decode signal DEC_SC0 and the first sub-channel command preparation signal CMD_PRE_SC0 may have opposite phases and be provided as control signals for the first transmission gate 752. The first transmission gate 752 may provide the fourth CS signal PCS_R2_FS to the first logic circuit 753 in response to the first sub-channel decode signal DEC_SC0 and the first sub-channel command preparation signal CMD_PRE_SC0. The first tri-state buffer 754 may be connected to an output and an input of the first logic circuit 753 and may be operated to cause the first logic circuit 753 to latch the first sub-channel command preparation signal CMD_PRE_SC0. The first sub-channel command preparation signal CMD_PRE_SC0 latched in the first logic circuit 753 may be output as a first sub-channel signal CMD_SC0 through the second inverter 755. The first sub-channel signal CMD_SC0 is interchangeably referred to as the SC0 command signal CMD_SC0.

The sub-channel command signal generating circuit 750 may include a third inverter 761, a second transmission gate 762, a second logic circuit 763, a second tri-state buffer 764, and a fourth inverter 765 to output the second sub-channel signal CMD_SC1 or the SC0 command signal CMD_SC0. The third inverter 761 may input the second sub-channel decode signal DEC_SC1, output a second sub-channel command preparation signal CMD_PRE_SC1, and provide the second sub-channel command preparation signal CMD_PRE_SC1 to the second logic circuit 763. The second sub-channel decode signal DEC_SC1 and the second sub-channel command preparation signal CMD_PRE_SC1 may have opposite phases and be provided as control signals for the second transmission gate 762. The second transmission gate 762 may provide the fourth CS signal PCS_R2_FS to the second logic circuit 763 in response to the second sub-channel decode signal DEC_SC1 and the second sub-channel command preparation signal CMD_PRE_SC1. The second tri-state buffer 764 may be connected to an output and an input of the second logic circuit 763 and may be operated to cause the second logic circuit 763 to latch the second sub-channel command preparation signal CMD_PRE_SC1. The second sub-channel command preparation signal CMD_PRE_SC1 latched in the second logic circuit 763 may be output as the second sub-channel signal CMD_SC1 through the fourth inverter 765.

As shown in FIG. 8, while the fourth CS signal PCS_R2_FS is at a logic high level, the sub-channel command signal generating circuit 750 may capture the first sub-channel decode signal DEC_SC0 to generate the SC0 command signal CMD_SC0 and capture the second sub-channel decode signal DEC_SC1 to generate the SC1 command signal CMD_SC1. The SC0 command signal CMD_SC0 and the SC1 command signal CMD_SC1 have a signal window of two clock cycles 2nCK.

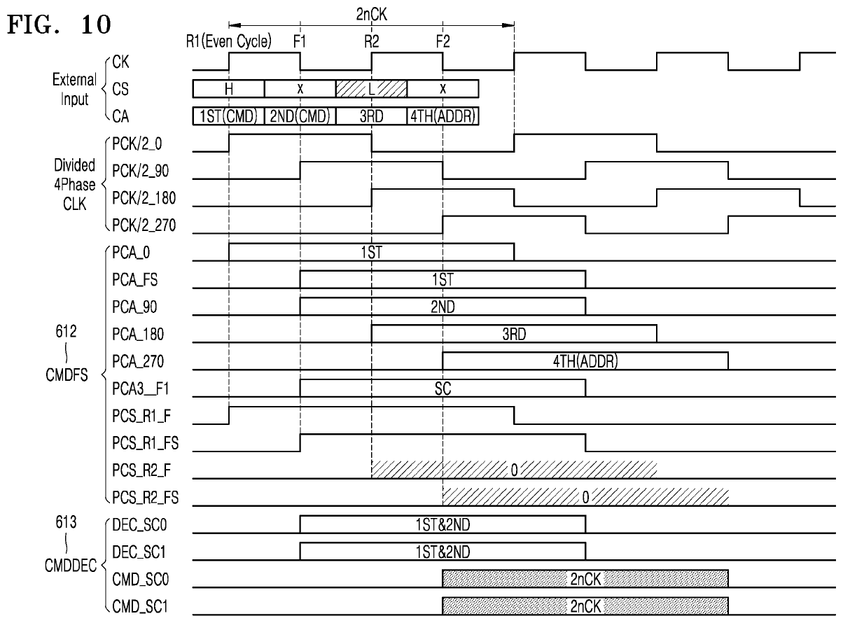

In some implementations, the pre-charge command PRE is normally applied when the chip select signal CS is applied at a logic high level at the first rising edge R1 and the second rising edge R2 of the clock signal CK, as shown in the pre-charge command diagram T500 of FIG. 5. However, the chip select signal CS may be abnormally applied with a logic low level at the second rising edge R2 of the clock signal CK. In this case, the third CS signal PCS_R2_F and the fourth CS signal PCS_R2_FS may be output at a logic low level. The first logic circuit 753 and the second logic circuit 763 of the sub-channel command signal generating circuit 750 may be disabled by the fourth CS signal PCS_R2_FS at the logic low level. As shown in FIG. 10, the SC0 command signal CMD_SC0 and the SC1 command signal CMD_SC1 may not be generated (shown in shaded form).

Again, referring to FIG. 6, the first logic circuit 614 may receive the SC0 command signal CMD_SC0 and the SC1 command signal CMD_SC1, perform an OR logic operation on the SC0 command signal CMD_SC0 and the SC1 command signal CMD_SC1, and provide an output of the OR logic operation to the address capturing circuit 615. The address capturing circuit 615 may capture the fourth command operand signal PCA_270, i.e., an address operand signal PCA_270, in response to the SC0 command signal CMD_SC0 or the SC1 command signal CMD_SC1 and output an address signal ADDR. The address signal ADDR captured by the address capturing circuit 615 may be provided to the second logic circuit 618 through the first buffer 616 and to a second logic circuit 628 of the second CA circuit 141 through the second buffer 617. The first buffer 616 may include a tri-state buffer enabled in response to the SC0 command signal CMD_SC0, and the second buffer 617 may include a tri-state buffer enabled in response to the SC1 command signal CMD_SC1. The second logic circuit 618 may receive the address signal ADDR transmitted through the first buffer 616 and the address signal ADDR transmitted through a second buffer 627 of the second CA circuit 141, perform an OR logic operation, and output an output signal of the OR logic operation as an SC0 address signal SC0_ADDR. The SC0 address signal SC0_ADDR refers to an address signal for accessing the SC0 memory region 130.

The second CA circuit 141 is different from the first CA circuit 140 in that the second CA circuit 141 receives the CA signal and the chip select signal CS transmitted from the memory controller 110 through the SC1 channel 161, and circuit elements of the second CA circuit 141 may be identical to those of the first CA circuit 140. Descriptions of the second CA circuit 141 identical to those of the first CA circuit 140 are omitted.

The SC1 CA circuit 141 may include a CA buffer circuit 621, a command capturing circuit 622, a command decoder circuit 623, a first logic circuit 624, an address capturing circuit 625, a first buffer 626, the second buffer 627, and the second logic circuit 628. The CA buffer circuit 621 may receive the CA signal at a CML level transmitted from the memory controller 110 through the SC1 channel 161 and output the CA signal at a CMOS level. The command capturing circuit 622 may capture the chip select signal CS and the CA signal output from the CA buffer circuit 621 in response to the first to fourth phase clock signals PCK/2_0, PCK/2_90, PCK/2_180, and PCK/2_270 and output first to third command operand signals PCA_FS, PCA_F1, and PCA_180, the address operand signal PCA_270, the sub-channel designation signal PCA3_F1, the second CS signal PCS_R1_FS, and the fourth CS signal PCS_R2_FS.

The command decoder circuit 623 may generate an SC0 command signal CMD_SC0 for accessing the SC0 memory region 130 and an SC1 command signal CMD_SC1 for accessing the SC1 memory region 131, based on the first command operand signal PCA_FS, the second command operand signal PCA_F1, the second CS signal PCS_R1_FS, and the sub-channel designation signal PCA3_F1. The first logic circuit 624 may receive the SC0 command signal CMD_SC0 and the SC1 command signal CMD_SC1, perform an OR logic operation, and provide an output signal of the OR logic operation to the address capturing circuit 625. The address capturing circuit 625 may capture the an address operand signal PCA_270 in response to the SC0 command signal CMD_SC0 or the SC1 command signal CMD_SC1 and output an address signal ADDR.

The address signal ADDR captured by the address capturing circuit 625 may be provided to the second logic circuit 618 through the first buffer 626 and to a second logic circuit 628 of the SC0 CA circuit 140 through the second buffer 627. The first buffer 626 may include a tri-state buffer enabled in response to the SC1 command signal CMD_SC1, and the second buffer 627 may include a tri-state buffer enabled in response to the SC0 command signal CMD_SC0. The second logic circuit 628 may receive the address signal ADDR transmitted through the first buffer 626 and the address signal ADDR transmitted through a second buffer 627 of the SC0 CA circuit 140, perform an OR logic operation, and output an output signal of the OR logic operation as an SC1 address signal SC1_ADDR. The SC1 address signal SC1_ADDR refers to an address signal for accessing the SC1 memory region 131.

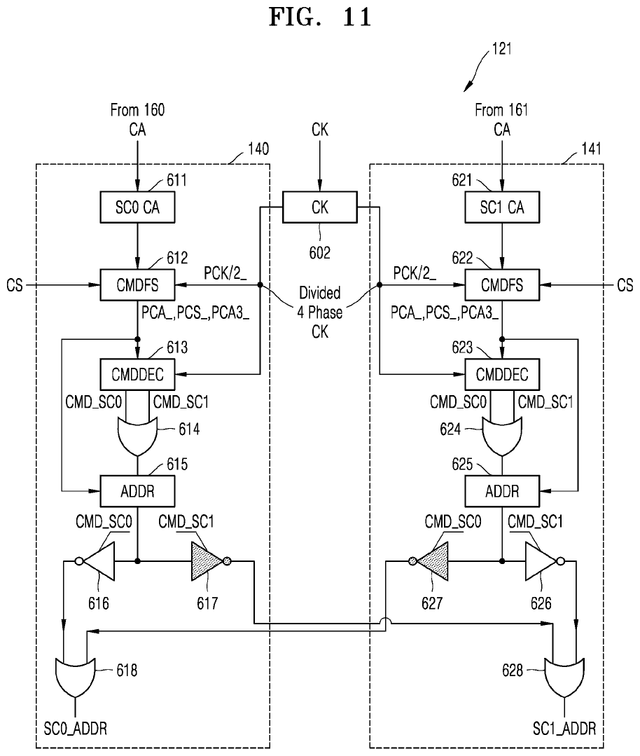

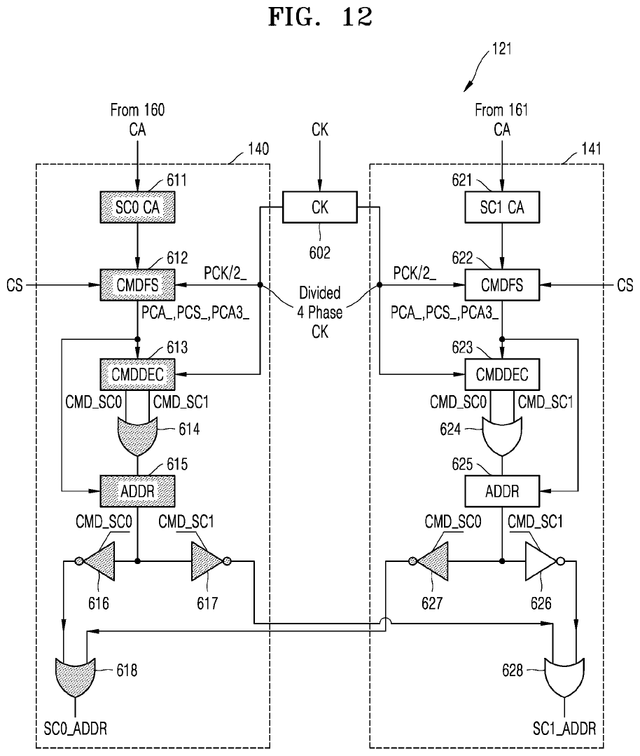

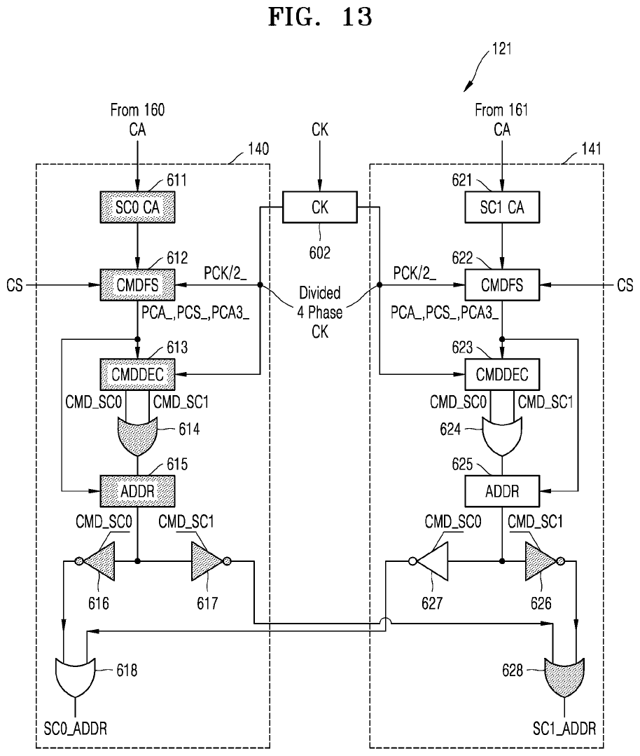

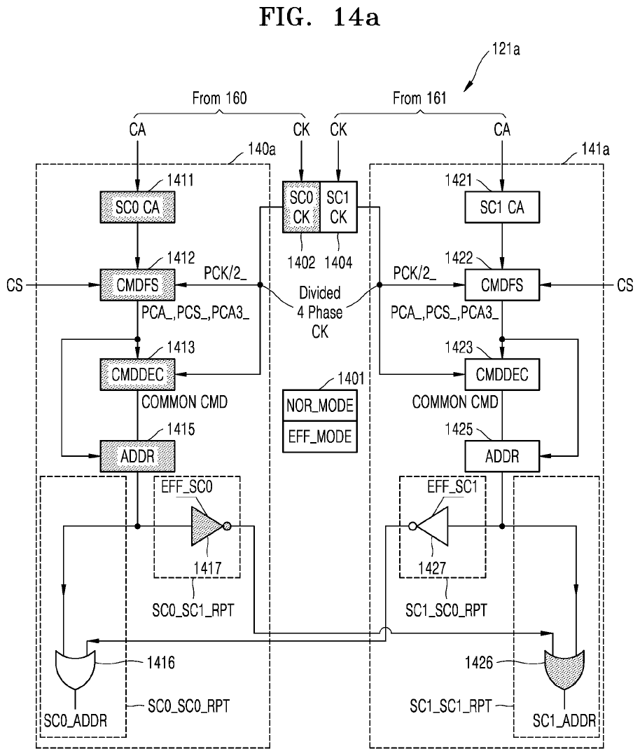

FIGS. 11, 12, and 13 are diagrams illustrating the operation of the command address circuit of FIG. 6. FIG. 11 shows the case where the memory device 121 operates in the normal mode described with reference to FIG. 1. FIG. 12 shows the case where the memory device 121 operates in the SC=1 efficiency mode described with reference to FIG. 2B, and FIG. 13 shows the case where the memory device 121 operates in the SC=0 efficiency mode described with reference to FIG. 2C.

Referring to FIG. 1 and FIG. 11, when the memory device 121 is in the normal mode, the second buffer 617 of the SC0 CA circuit 140 and the second buffer 627 of the SC1 CA circuit 141 may be disabled, and the remaining circuit elements of the SC0 CA circuit 140 and the SC1 CA circuit 141 may be enabled. Therefore, the SC0 CA circuit 140 may capture the CA signal received by the SC0 CA circuit 140 and output a captured CA signal as the SC0 address signal SC0_ADDR and the SC1 CA circuit 141 may capture the CA signal received by the SC1 CA circuit 141 and output a captured CA signal as the SC1 address signal SC1_ADDR.

Referring to FIG. 2B and FIG. 12, when the memory device 121 is in the SC=1 efficiency mode, the SC0 CA circuit 140 and the second buffer 627 of the SC1 CA circuit 141 may disabled, and the remaining circuit elements of the SC1 CA circuit 141 may be enabled. Therefore, the SC1 CA circuit 141 may capture the CA signal received by the SC1 CA circuit 141 and output a captured CA signal as the SC1 address signal SC1_ADDR.

Referring to FIG. 2C and FIG. 13, when the memory device 121 is in the SC=0 efficiency mode, in the SC0 CA circuit 140, only the second logic circuit 618 may be enabled, and the remaining circuit elements of the SC0 CA circuit 140 may be disabled. In the SC1 CA circuit 141, only the first buffer 626 and the second logic circuit 628 may be disabled, and the remaining circuit elements may be enabled. Therefore, the SC1 CA circuit 141 may capture the CA signal received by the SC1 CA circuit 141 and output a captured CA signal as the SC0 address signal SC0_ADDR.

FIGS. 14A and 14B are diagrams illustrating example command address circuits 140a and 141a of a memory device 121a. Hereinafter, subscripts attached to the same reference numerals in different drawings (e.g., a in 121a and b in 121b) are used to distinguish a plurality of components that perform similar or identical functions. Descriptions of CA circuits 140a and 141a identical to those of the CA circuits 140 and 141 of FIG. 6 are omitted.

Referring to FIG. 14A, the memory device 121a is different from the memory device 121 of FIG. 6 in that the memory device 121a receives the clock signal CK from the memory controller 110 through the SC0 channel 160 and receives the clock signal CK through the SC1 channel 161. In other words, each sub-channel may include the clock signal CK. The first clock circuit 1402 may divide the clock signal CK received through the SC0 channel 160 by two, generate multi-phase clock signals that are phase-divided from the divided-by-2 clock signal CK, and provide the multi-phase clock signals to an SC0 CA circuit 140a. The second clock circuit 1404 may divide the clock signal CK received through the SC1 channel 161 by two, generate multi-phase clock signals that are phase-divided from the divided-by-2 clock signal CK, and provide the multi-phase clock signals to an SC1 CA circuit 141a.

The SC0 CA circuit 140a and the SC1 CA circuit 141a are different from the SC0 CA circuit 140 and the SC1 CA circuit 141 of FIG. 6 in that the SC0 CA circuit 140a and the SC1 CA circuit 141a do not include first logic circuits 614 and 624. This means that a command decoder circuit 1413 of the SC0 CA circuit 140a generates a common command signal COMMON_CMD for the SC0 memory region 130 and the SC1 memory region 131 without distinguishing between the SC0 command signal CMD_SC0 for accessing the SC0 memory region 130 and the SC1 command signal CMD_SC1 for accessing the SC1 memory region 131.

The SC0 CA circuit 140a may include a CA buffer circuit 1411, a command capturing circuit 1412, the command decoder circuit 1413, an address capturing circuit 1415, a logic circuit 1416, and a buffer 1417. The logic circuit 1416 may receive an output of the address capturing circuit 1415 of the SC0 CA circuit 140a and an output of the buffer 1427 of the SC1 CA circuit 141a, perform an OR logic operation, and output an output signal of the OR logic operation as the SC0 address signal SC0_ADDR. The buffer 1417 may provide the output of the address capturing circuit 1415 of the SC0 CA circuit 140a to a logic circuit 1426 of the SC1 CA circuit 141a in response to an SC0 efficiency signal EFF_SC0. When the memory device 121a operates in the efficiency mode and the sub-channel signal SC, which is set to the column address CA[3] and transmitted through a CA signal line, is set to a logic low level (i.e., when SC=0), the SC0 efficiency signal EFF_SC0 may be activated to a logic high level.

The SC1 CA circuit 141a may include a CA buffer circuit 1421, a command capturing circuit 1422, a command decoder circuit 1423, an address capturing circuit 1425, the logic circuit 1426, and a buffer 1427. The logic circuit 1426 may receive an output of the address capturing circuit 1425 of the SC1 CA circuit 141a and an output of the buffer 1417 of the SC0 CA circuit 140a, perform an OR logic operation, and output an output signal of the OR logic operation as the SC1 address signal SC1_ADDR. The buffer 1427 may provide the output of the address capturing circuit 1425 of the SC1 CA circuit 141a to a logic circuit 1416 of the SC0 CA circuit 140a in response to an SC1 efficiency signal EFF_SC1. When the memory device 121a operates in the efficiency mode and the sub-channel signal SC, which is set to the column address CA[3] and transmitted through a CA signal line, is set to a logic high level (i.e., when SC=1), the SC1 efficiency signal EFF_SC1 may be activated to a logic high level.

In some implementations, the logic circuit 1416 is referred to as an SC0_SC0 repeater circuit SC0_SC0_RPT based on its operation of providing an address operand captured by the SC0 CA circuit 140a as the SC0 address signal SC0_ADDR. The buffer 1417 may be referred to as an SC0_SC1 repeater circuit SC0_SC1_RPT based on its operation of providing an address operand captured by the SC0 CA circuit 140a as the SC1 address signal SC1_ADDR. The logic circuit 1426 may be referred to as an SC1_SC1 repeater circuit SC1_SC1_RPT based on its operation of providing an address operand captured by the SC1 CA circuit 141a as the SC1 address signal SC1_ADDR. The buffer 1427 may be referred to as an SC1_SC0 repeater circuit SC1_SC0_RPT based on its operation of providing an address operand captured by the SC1 CA circuit 141a as the SC1 address signal SC1_ADDR.

The memory device 121a may operate in a normal mode NOR_MODE or an efficiency mode EFF_MODE set in an MRS 1401. FIG. 14A shows the memory device 121a in the SC=0 efficiency mode. The first clock circuit 1402 is disabled, and, in the SC0 CA circuit 140a, only the SC0_SC0 repeater circuit SC0_SC0_RPT may be enabled and the remaining circuit elements of the SC0 CA circuit 140a may be disabled. In the SC1 CA circuit 141a, only the SC1_SC1 repeater circuit SC1_SC1_RPT may be disabled, and the remaining circuit elements of the SC1 CA circuit 141a may be enabled. Therefore, the SC1 CA circuit 141a may capture the CA signal received by the SC1 CA circuit 141a and output a captured CA signal as the SC0 address signal SC0_ADDR.

Referring to FIG. 14B, states of repeater circuits SC0_SC0_RPT, SC0_SC1_RPT, SC1_SC0_RPT, and SC1_SC1_RPT according to operation modes of the memory device 121a are shown. In the normal mode, the SC0_SC0 repeater circuit SC0_SC0_RPT circuit and the SC1_SC1 repeater circuit SC1_SC1_RPT are enabled, the SC0_SC1 repeater circuit SC0_SC1_RPT is disabled as the SC0 efficiency signal EFF_SC0 is deactivated to a logic low level, and the SC1_SC0 repeater circuit SC1_SC0_RPT is disabled as the SC1 efficiency signal EFF_SC1 is deactivated to a logic low level. Therefore, an address operand captured by the SC0 CA circuit 140a may be output as the SC0 address signal SC0_ADDR through the SC0_SC0 repeater circuit SC0_SC0_RPT, and an address operand captured by the SC1 CA circuit 141a may be output as the SC1 address signal SC1_ADDR through the SC1_SC1 repeater circuit SC1_SC1_RPT.

In the SC=1 efficiency mode, the SC0_SC0 repeater circuit SC0_SC0_RPT is disabled, and, as the SC0 efficiency signal EFF_SC0 is deactivated to a logic low level. The SC0_SC1 repeater circuit SC0_SC1_RPT is also disabled. As the SC1 efficiency signal EFF_SC1 is activated to a logic high level, the SC1_SC0 repeater circuit SC1_SC0_RPT is enabled, and the SC1_SC1 repeater circuit SC1_SC1_RPT is also enabled. Therefore, the SC0 address signal SC0_ADDR may not be output by the SC0 CA circuit 140a as the SC0_SC0 repeater circuit SC0_SC0_RPT is disabled, and an address operand captured by the SC1 CA circuit 141a may be output as the SC1 address signal SC1_ADDR through the SC1_SC1 repeater circuit SC1_SC1_RPT.

In the SC=0 efficiency mode, the SC0_SC0 repeater circuit SC0_SC0_RPT is enabled, and, as the SC0 efficiency signal EFF_SC0 is deactivated to a logic low level, the SC0_SC1 repeater circuit SC0_SC1_RPT is disabled. As the SC1 efficiency signal EFF_SC1 is activated to a logic high level, the SC1_SC0 repeater circuit SC1_SC0_RPT is enabled, and the SC1_SC1 repeater circuit SC1_SC1_RPT is disabled. Therefore, the SC1 address signal SC1_ADDR may not be output by the SC1 CA circuit 141a as the SC1_SC1 repeater circuit SC1_SC1_RPT is disabled, and an address operand captured by the SC1 CA circuit 141a may be output as the SC0 address signal SC0_ADDR through the SC1_SC0 repeater circuit SC1_SC0_RPT.

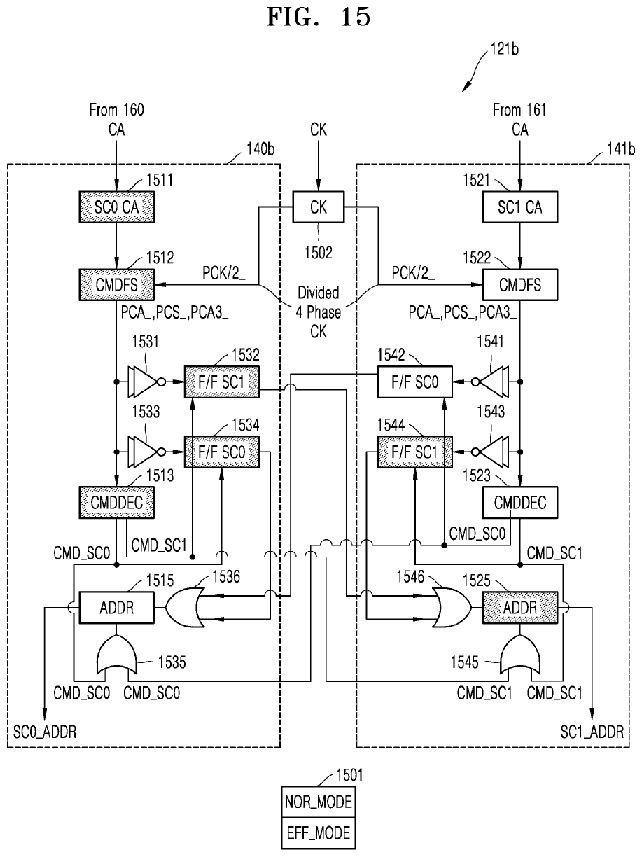

FIG. 15 is a diagram illustrating the CA circuits 140b and 141b of a memory device 121b according to implementations. Descriptions of CA circuits 140b and 141b identical to those of the CA circuits 140 and 141 of FIG. 6 are omitted.

Referring to FIG. 15, the memory device 121b may include an MRS 1501, a clock circuit 1402, an SC0 CA circuit 140b, and an SC1 CA circuit 141b. The SC0 CA circuit 140b may include a CA buffer circuit 1511, a command capturing circuit 1512, a command decoder circuit 1513, an address capturing circuit 1515, a first buffer 1531, a first flip-flop circuit 1532, a second buffer 1533, a second flip-flop circuit 1534, a first logic circuit 1535, and a second logic circuit 1536.

In some implementations, the memory device 121b receives a separate clock signal CK for each sub-channel. As shown in FIG. 14A, the memory device 121 may divide the clock signal CK, which is received by a first clock circuit 1402 for an SC0 channel and by a second clock circuit 1404 for an SC1 channel, by two and generate a multi-phase clock signal that is phase-divided from a divided-by-two clock signal CK.

The SC1 CA circuit 141b is configured identically to the SC0 CA circuit 140b and may include a CA buffer circuit 1521, a command capturing circuit 1522, a command decoder circuit 1523, an address capturing circuit 1525, a first buffer 1541, a first flip-flop circuit 1542, a second buffer 1543, a second flip-flop circuit 1544, a first logic circuit 1545, and a second logic circuit 1546.

In the SC0 CA circuit 140b, the first buffer 1531, the first flip-flop circuit 1532, the second buffer 1533, and the second flip-flop circuit 1534 may latch address operand signals captured by the command capturing circuit 1512. The first flip-flop circuit 1532 may latch an address operand signal in response to the SC1 command signal CMD_SC1, and the second flip-flop circuit 1534 may latch an address operand signal in response to the SC0 command signal CMD_SC0. The first logic circuit 1535 may receive the SC0 command signal CMD_SC0 provided from the command decoder circuit 1513 and the SC0 command signal CMD_SC0 provided from the command decoder circuit 1523 of the SC1 CA circuit 141b, perform an OR logic operation, and provide an output signal of the OR logic operation to the address capturing circuit 1515. The second logic circuit 1536 may receive an address operand signal captured by the second flip-flop circuit 1534 and an address operand signal captured by the first flip-flop circuit 1542 of the SC1 CA circuit 141b, perform an OR logic operation, and provide an output signal of the OR logic operation to the address capturing circuit 1515. The address capturing circuit 1515 may capture an address operand signal output from the second logic circuit 1536 in response to the SC0 command signal CMD_SC0 output from the first logic circuit 1535 and output a captured address operand signal as the SC0 address signal SC0_ADDR.

In the SC1 CA circuit 141b, the first buffer 1541, the first flip-flop circuit 1542, the second buffer 1543, and the second flip-flop circuit 1544 may latch address operand signals captured by the command capturing circuit 1522. The first flip-flop circuit 1542 may latch an address operand signal in response to the SC0 command signal CMD_SC0, and the second flip-flop circuit 1544 may latch an address operand signal in response to the SC1 command signal CMD_SC1. The first logic circuit 1545 may receive the SC1 command signal CMD_SC1 provided from the command decoder circuit 1523 and the SC1 command signal CMD_SC1 provided from the command decoder circuit 1513 of the SC0 CA circuit 140b, perform an OR logic operation, and provide an output signal of the OR logic operation to the address capturing circuit 1525. The second logic circuit 1546 may receive an address operand signal captured by the second flip-flop circuit 1544 and an address operand signal captured by the first flip-flop circuit 1532 of the SC0 CA circuit 140b, perform an OR logic operation, and provide an output signal of the OR logic operation to the address capturing circuit 1525. The address capturing circuit 1525 may capture an address operand signal output from the second logic circuit 1546 in response to the SC1 command signal CMD_SC1 output from the first logic circuit 1545 and output a captured address operand signal as the SC1 address signal SC1_ADDR.

The memory device 121b may operate in the normal mode NOR_MODE or the efficiency mode EFF_MODE set in an MRS 1501. FIG. 15 shows the memory device 121b in the SC=0 efficiency mode. In the SC0 CA circuit 140b, only the first logic circuit 1535, the second logic circuit 1536, and the address capturing circuit 1515 may be enabled, and the remaining circuit elements of the SC0 CA circuit 140b may be disabled. In the SC1 CA circuit 141b, only the address capturing circuit 1525 and the second flip-flop circuit 1544 may be disabled, and the remaining circuit elements of the SC1 CA circuit 141b may be enabled. Therefore, the address capturing circuit 1515 of the SC0 CA circuit 140b may capture an address operand signal output from the first flip-flop circuit 1542 of the SC1 CA circuit 141b and output a captured address operand signal as the SC0 address signal SC0_ADDR.

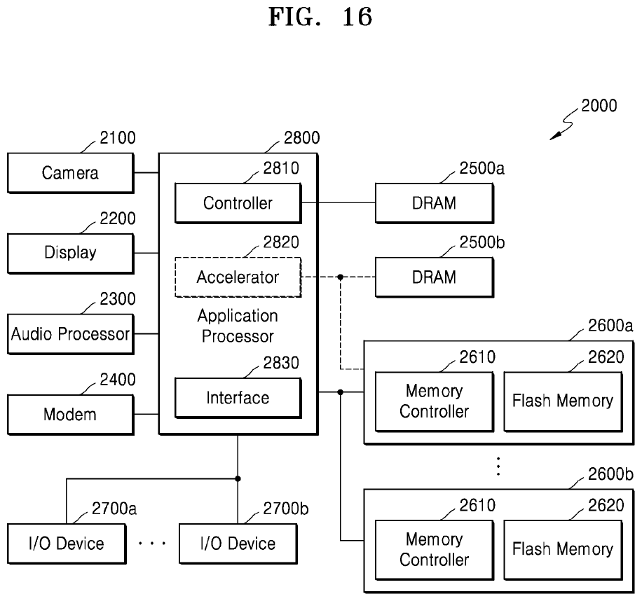

FIG. 16 is a block diagram of a system 2000 for describing an electronic device including a semiconductor IC according to implementations.

Referring to FIG. 26, the system 2000 may include a camera 2100, a display 2200, an audio processor 2300, a modem 2400, DRAMs 2500a and 2500b, flash memories 2600a and 2600b, I/O devices 2700a and 2700b, and an AP 2800. The system 2000 may be implemented as a laptop computer, a mobile phone, a smartphone, a tablet PC, a wearable device, a healthcare device, or an IoT device. Also, the system 2000 may be implemented as a server or a PC.

The camera 2100 may capture a still image or a video according to a user's control and may store captured image/video data or transmit the captured image/video data to the display 2200. The audio processor 2300 may process audio data included in the flash memories 2600a and 2600b or network content. The modem 2400 may transmit a modulated signal for wired/wireless data transmission/reception to a receiver and the modulated signal may be demodulated by the receiver to restore an original signal. The I/O devices 2700a and 2700b may include devices providing a digital input function and/or digital output function, e.g., a Universal Serial Bus (USB), a storage, a digital camera, a Secure Digital (SD) card, a Digital Versatile Disc (DVD), a network adapter, a touch screen, etc.

The AP 2800 may control the overall operation of the system 2000. The AP 2800 may include a control block 2810, an accelerator block or accelerator chip 2820, and an interface block 2830. The AP 2800 may control the display 2200, such that a part of content stored in the flash memories 2600a and 2600b is displayed on the display 2200. When a user input is received through the I/O devices 2700a and 2700b, the AP 2800 may perform a control operation corresponding to the user input. The AP 2800 may include an accelerator block, which is a circuit dedicated for calculation of artificial intelligence (AI) data, or may include an accelerator chip 2820 separately from the AP 2800. The DRAM 2500b may be additionally provided in the accelerator block or the accelerator chip 2820. The accelerator block is a functional block that specializes in performing a particular function of the AP 2800 and may include a GPU, which is a functional block that specializes in processing graphic data, a neural processing unit (NPU), which is a block that specializes in AI calculation and inference, and a data processing unit (DPU), which is a block that specializes in data transmission. According to an implementation, an image captured by a user through the camera 2100 is signal-processed and stored in the DRAM 2500b, and the accelerator block or accelerator chip 2820 may perform AI data calculation for recognizing data using data stored in the DRAM 2500b and a function used for inference.

The system 2000 may include a plurality of DRAMs 2500a and 2500b. The AP 2800 may set up a DRAM interface protocol and communicate with the DRAMs 2500a and 2500b to control the DRAMs 2500a and 2500b through commands complying with the JEDEC standard and mode register (MRS) setting or to use company-specific functions such as low voltage/high-speed/reliability and a cyclic redundancy check (CRC)/error correction code (ECC) function. For example, the AP 2800 may communicate with the DRAM 2500a through an interface complying with the JEDEC standards such as LPDDR4 and LPDDR5, and the accelerator block or the accelerator chip 2820 may set and use a new DRAM interface protocol to control the DRAM 2500b for an accelerator, which has a greater bandwidth than the DRAM 2500a.

Although FIG. 16 shows only the DRAMs 2500a and 2500b, the present disclosure is not limited thereto. As long as a bandwidth, a response speed, and voltage conditions of the AP 2800 or the accelerator chip 2820 are satisfied, any memory like a PRAM, an SRAM, an MRAM, an RRAM, an FRAM, or a Hybrid RAM may be used. The DRAMs 2500a and 2500b have relatively smaller latency and bandwidth than the I/O devices 2700a and 2700b or the flash memories 2600a and 2600b. The DRAMs 2500a and 2500b are initialized when the system 2000 is powered on and the OS and application data are loaded thereto, and thus the DRAMs 2500a and 2500b may be used as temporary storages for the OS and the application data or may be used as execution spaces for various software code.

In the DRAMs 2500a and 2500b, four arithmetic operations (i.e., addition, subtraction, multiplication, and division), vector calculations, address calculations, or Fast Fourier Transform (FFT) calculations may be performed. Also, in the DRAMs 2500a and 2500b, a function for an operation used for an inference may be performed. Here, the inference may be performed in a deep learning algorithm using an artificial neural network. The deep learning algorithm may include a training operation for learning a model through various data and an inference operation for recognizing data with the trained model.

The system 2000 may include a plurality of storages or flash memories 2600a and 2600b having a larger capacity than the DRAMs 2500a and 2500b. The accelerator block or accelerator chip 2820 may perform a training operation and an Al data calculation using the flash memories 2600a and 2600b. According to an implementation, the flash memories 2600a and 2600b may include a memory controller 2610 and a flash memory device 2620, and a training operation and an inference AI data calculation performed by the AP 2800 and/or the accelerator chip 2820 may be performed more efficiently by using an arithmetic unit included in the memory controller 2610. The flash memories 2600a and 2600b may store images captured through the camera 2100 or data transmitted through a data network. For example, the flash memories 2600a and 2600b may store Augmented Reality/Virtual Reality content, High Definition (HD) content, or Ultra High Definition (UHD) content.

In the system 2000, the bank groups of the DRAMs 2500a and 2500b may each be referred to as a sub-channel memory region and may include a CA circuit and a DQ circuit connected to each of corresponding sub-channels. The control block 2810 of the AP 2800 may control the power of the DRAMs 2500a and 2500b. The control block 2810 may control the normal mode operation of activating all sub-channels and accessing sub-channel memory regions and may control the power efficiency mode operation of activating even-numbered sub-channels of sub-channels and deactivating odd-numbered sub-channels.

The DRAMs 2500a and 2500b may each include a first CA circuit and a second CA circuit, wherein the first CA circuit may generate a first sub-channel command signal, a second sub-channel command signal, and a first sub-channel address signal based on first command address signals of first sub-channel signals, and the second CA circuit may generate a third sub-channel command signal, a fourth sub-channel command signal, and a second sub-channel address signal based on second command address signals of second sub-channel signals. In the power efficiency mode, the first CA circuit may be disabled and the second CA circuit may generate the first sub-channel address signal in response to the third sub-channel command signal. Alternatively, the first CA circuit may be disabled and the second CA circuit may generate the second sub-channel address signal in response to the fourth sub-channel command signal. The DRAMs 2500a and 2500b may each even-number clock signal cycles based on the clock signal when a first chip select signal is input after power down, determine that a command applied in an even-numbered clock cycle is valid, and determine that a command applied in an odd-numbered clock cycle is invalid. The first CA circuit and the second CA circuit may be disabled such that first and second sub-channel command signals and third and fourth sub-channel command signals are not generated based on the logic level of a chip select signal of first and second command address signals at a first rising edge or a second rising edge of a clock signal, as described above with reference to FIG. 10. By using the DRAMs 2500a and 2500b that perform power efficiency mode operations, command timing speed may be increased and low power consumption characteristics may be achieved. Such memory devices may be usefully applied to low-power and high-speed communication devices and systems.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although various examples have been described with reference to the accompanying drawings, concepts described herein can be carried out in other specific forms without departing from the scope of this disclosure. Therefore, the above examples should be considered illustrative.

1. A memory device supporting a power efficiency mode, the memory device comprising:
a memory cell array region comprising a plurality of memory cells, wherein the memory cell array region comprises a first sub-channel memory cell array region and a second sub-channel memory cell array region;
a plurality of signal pins connected to a plurality of signal lines, wherein the plurality of signal pins comprise first sub-channel signal pins and second sub-channel signal pins, the first sub-channel signal pins are configured to receive first sub-channel signals associated with the first sub-channel memory cell array region, and the second sub-channel signal pins are configured to receive second sub-channel signals associated with the second sub-channel memory cell array region;
a first command address circuit configured to receive first command address signals of the first sub-channel signals, and generate a first sub-channel command signal, a second sub-channel command signal, and a first sub-channel address signal based on the first command address signals; and
a second command address circuit configured to receive second command address signals of the second sub-channel signals, and generate a third sub-channel command signal, a fourth sub-channel command signal, and a second sub-channel address signal based on the second command address signals,
wherein, in the power efficiency mode, the first command address circuit is configured to be disabled, and the second command address circuit is configured to generate the first sub-channel address signal in response to the third sub-channel command signal.

2. The memory device of claim 1, wherein, in the power efficiency mode, the first command address circuit is configured to be disabled and the second command address circuit is configured to generate the second sub-channel address signal in response to the fourth sub-channel command signal.

3. The memory device of claim 1, further comprising a clock circuit configured to receive a clock signal,
wherein the clock circuit is configured to (i) divide the clock signal by two to generate a division clock signal and (ii) generate four phase clock signals that are phase-divided from the division clock signal, and
wherein the four phase clock signals comprise a first phase clock signal, a second phase clock signal, a third phase clock signal and a fourth phase clock signal, and the four phase clock signals have a phase difference of 90 degrees with respect to each other.

4. The memory device of claim 3, wherein each of the first command address circuit and the second command address circuit further comprises a command capturing circuit configured to receive the first command address signals or the second command address signals, and
wherein the command capturing circuit is configured to:
capture the first command address signals or the second command address signals in response to the first phase clock signal and the second phase clock signal to generate a first command operand signal and a first chip select signal;
capture (i) the first command address signals or the second command address signals and (ii) the first chip select signal in response to the second phase clock signal to generate a second command operand signal, a second chip select signal, and a sub-channel designation signal;
capture the first command address signals or the second command address signals in response to third phase clock signal to generate a third command operand signal and a third chip select signal; and
capture (i) the first command address signals or the second command address signals and (ii) the third chip select signal in response to the fourth phase clock signal to generate an address operand signal and a fourth chip select signal.

5. The memory device of claim 4, wherein each of the first and second command address circuits further comprises a command decoder circuit configured to generate (i) the first and second sub-channel command signals, or (ii) the third and fourth sub-channel command signals, based on the first command operand signal, the second command operand signal, the second chip select signal, and the sub-channel designation signal.

6. The memory device of claim 4, wherein the sub-channel designation signal comprises a signal indicating which of the first and second sub-channel memory cell array regions is accessed in the power efficiency mode.

7. The memory device of claim 5, wherein the first command address circuit comprises:
a first logic circuit configured to receive the first or second sub-channel command signals;
a first address capturing circuit configured to capture the address operand signal in response to an output of the first logic circuit and output a first address signal;
a first buffer configured to transmit the first address signal to a second logic circuit in response to the first sub-channel command signal;
a second buffer configured to transmit the first address signal to the second command address circuit in response to a second sub-channel command signal; and
the second logic circuit configured to output the first sub-channel address signal based on the first address signal transmitted through the first buffer or the second address signal transmitted through a third buffer of the second command address circuit.

8. The memory device of claim 7, wherein the second command address circuit comprises:
a third logic circuit configured to receive the third or fourth sub-channel command signals;
a second address capturing circuit configured to capture the address operand signal in response to an output of the third logic circuit and output a second address signal;
the third buffer configured to transmit the second address signal to the first command address circuit in response to the third sub-channel command signal;
a fourth buffer configured to transmit the second address signal to a fourth logic circuit in response to the fourth sub-channel command signal; and
the fourth logic circuit configured to output the second sub-channel address signal based on the first address signal transmitted through the second buffer or the second address signal transmitted through the fourth buffer of the second command address circuit.

9. The memory device of claim 5, wherein the first command address circuit comprises:
a first flip-flop circuit configured to latch the address operand signal in response to a first command signal and output a first address signal;
a second flip-flop circuit configured to latch the address operand signal in response to a second command signal and output a second address signal;
a first logic circuit configured to receive the first command signal or a third command signal;
a second logic circuit configured to receive the first address signal or a third address signal output from a third flip-flop circuit of the second command address circuit; and
a first address capturing circuit configured to capture the first address signal or the third address signal output from the second logic circuit in response to the first command signal or the third command signal output from the first logic circuit and output the first sub-channel address signal.

10. The memory device of claim 9, wherein the second command address circuit comprises:
a third flip-flop circuit configured to latch the address operand signal in response to a third command signal and output the third address signal;
a fourth flip-flop circuit configured to latch the address operand signal in response to a fourth command signal and output a fourth address signal;
a third logic circuit configured to receive the second command signal or the fourth command signal;
a fourth logic circuit configured to receive the fourth address signal or the second address signal output from the second flip-flop circuit of the first command address circuit; and
a second address capturing circuit configured to capture the second address signal or the fourth address signal output from the fourth logic circuit in response to the second command signal or the fourth command signal output from the third logic circuit and output the second sub-channel address signal.

11. A memory device supporting a power efficiency mode, the memory device comprising:
a memory cell array region comprising a plurality of memory cells, wherein the memory cell array region comprises a first sub-channel memory cell array region and a second sub-channel memory cell array region;
a plurality of signal pins connected to a plurality of signal lines, wherein the plurality of signal pins comprise first sub-channel signal pins and second sub-channel signal pins, the first sub-channel signal pins are configured to receive first sub-channel signals associated with the first sub-channel memory cell array region, and the second sub-channel signal pins are configured to receive second sub-channel signals associated with the second sub-channel memory cell array region;
a first command address circuit configured to receive first command address signals of the first sub-channel signals and generate a first sub-channel command signal, based on the first command address signals and a first sub-channel efficiency signal; and
a second command address circuit configured to receive second command address signals of the second sub-channel signals and generate a second sub-channel command signal, based on the second command address signals and a second sub-channel efficiency signal,
wherein, in the power efficiency mode, the first sub-channel efficiency signal is activated based on a first logic level of a sub-channel signal, which is included in the first command address signals and indicates which of the first sub-channel memory cell array region and the second sub-channel memory cell array region is accessed, and the second sub-channel efficiency signal is activated when the sub-channel signal is at a second logic level different from the first logic level, and,
wherein in the power efficiency mode, the first command address circuit is configured to be disabled, and the second command address circuit is configured to generate a first sub-channel address signal in response to the second sub-channel efficiency signal.

12. The memory device of claim 11, wherein, in the power efficiency mode, the second command address circuit is configured to be disabled, and the first command address circuit is configured to generate a second sub-channel address signal in response to the first sub-channel efficiency signal.

13. The memory device of claim 11, further comprising a clock circuit for receiving a clock signal,
wherein the clock circuit is configured to (i) divide the clock signal by two to generate a division clock signal and (ii) generate four phase clock signals that are phase-divided from the division clock signal, and
wherein the four phase clock signals comprise a first phase clock signal, a second phase clock signal, a third phase clock signal and a fourth phase clock signal, and the four phase clock signals have a phase difference of 90 degrees with respect to each other.

14. The memory device of claim 13, wherein the clock circuit comprises:
a first clock circuit configured to receive a first clock signal of the first sub-channel signals related to the first sub-channel memory cell array region; and
a second clock circuit configured to receive a second clock signal of the second sub-channel signals related to the second sub-channel memory cell array region.

15. The memory device of claim 13, wherein each of the first command address circuit and the second command address circuit further comprises a command capturing circuit configured to receive the first command address signals or the second command address signals, and
wherein the command capturing circuit is configured to:
capture the first command address signals or the second command address signals in response to the first phase clock signal and the second phase clock signal to generate a first command operand signal and a first chip select signal;
capture (i) the first command address signals or the second command address signals and (ii) the first chip select signal in response to the second phase clock signal to generate a second command operand signal, a second chip select signal, and a sub-channel designation signal;
capture the first command address signals or the second command address signals in response to the third phase clock signal to generate a third command operand signal and a third chip select signal; and
capture (i) the first command address signals or the second command address signals and (ii) the third chip select signal in response to the fourth phase clock signal to generate an address operand signal and a fourth chip select signal.

16. The memory device of claim 15, wherein each of the first command address circuit and the second command address circuit further comprises a command decoder circuit configured to generate a common command signal for the first sub-channel memory cell array region or the second sub-channel memory cell array region, based on the first command operand signal, the second command operand signal, the second chip select signal, and the fourth chip select signal.

17. The memory device of claim 16, wherein the first command address circuit comprises:
a first address capturing circuit configured to capture the address operand signal and output a first address signal;
a first logic circuit configured to output the first sub-channel address signal based on the first address signal or a second address signal transmitted through a second buffer of the second command address circuit; and
a first buffer configured to transmit the first address signal to the second command address circuit in response to the first sub-channel efficiency signal.

18. The memory device of claim 17, wherein the second command address circuit comprises:
a second address capturing circuit configured to capture the address operand signal and output the second address signal;
a second logic circuit configured to output a second sub-channel address signal based on the second address signal or the first address signal transmitted through the first buffer of the first command address circuit; and
the second buffer configured to transmit the second address signal to the first command address circuit in response to the second sub-channel efficiency signal.

19. A memory device supporting a power efficiency mode, the memory device comprising:
a memory cell array region comprising a plurality of memory cells, wherein the memory cell array region comprises a first sub-channel memory cell array region and a second sub-channel memory cell array region;
a plurality of signal pins connected to a plurality of signal lines, wherein the plurality of signal pins comprise first sub-channel signal pins and second sub-channel signal pins, the first sub-channel signal pins are configured to receive first sub-channel signals associated with the first sub-channel memory cell array region, and the second sub-channel signal pins are configured to receive second sub-channel signals associated with the second sub-channel memory cell array region;
a first command address circuit configured to receive first command address signals of the first sub-channel signals and generate a first sub-channel command signal, a second sub-channel command signal, and a first sub-channel address signal based on the first command address signals;
a second command address circuit configured to receive second command address signals of the second sub-channel signals and generate a third sub-channel command signal, a fourth sub-channel command signal, and a second sub-channel address signal based on the second command address signals; and
an even-cycle detection circuit configured to detect even-number clock signal cycles based on a clock signal when a first chip select signal is input to the memory device after power-down of the memory device and detect whether a command is applied in the even-numbered clock signal cycles.

20. The memory device of claim 19, wherein the memory device is configured to determine that a command applied in the even-numbered clock cycle is valid and that a command applied in an odd-numbered clock cycle is invalid.

21-32. (canceled)
